(19) United States
(12) Patent Application Publication
(10) Pub. No.: US 2024/0136374 A1
(43) Pub. Date: Apr. 25, 2024

(54) IMAGE SENSOR

(71) Applicant: Samsung Electronics Co., Ltd., Suwon-si (KR)

(72) Inventor: Jung Wook LIM, Suwon-si (KR)

(73) Assignee: Samsung Electronics Co., Ltd., Suwon-si (KR)

(21) Appl. No.: 18/315,982

(22) Filed: May 10, 2023

(30) Foreign Application Priority Data
Oct. 24, 2022 (KR) 10-2022-0138645

(51) Int. Cl. H01L 27/146

(52) U.S. Cl. CPC H01L 27/14612; H01L 27/14603; H01L 27/1463; H01L 27/14636

(57) ABSTRACT

An image sensor comprises a first sub-pixel comprising a first photoelectric conversion region, a first floating diffusion region, and a first transfer transistor to transfer charges accumulated in the first photoelectric conversion region to the first floating diffusion region; and a second sub-pixel adjacent to the first sub-pixel, and comprising a second photoelectric conversion region, a second floating diffusion region, and a second transfer transistor to transfer charges accumulated in the second photoelectric conversion region to the second floating diffusion region. The first photoelectric conversion region may comprise a first and a second sub-region partitioned by a potential level isolation region that blocks movement of charges, and the first transfer transistor may comprise a first sub-transfer transistor to transfer charges accumulated in the first sub-region to the first floating diffusion region, and a second sub-transfer transistor to transfer charges accumulated in the second sub-region to the first floating diffusion region.

### CROSS-REFERENCE TO RELATED APPLICATION

This application claims priority from Korean Patent Application No. 10-2022-0138645 filed on Oct. 25, 2022 in the Korean Intellectual Property Office, and all the benefits accruing therefrom under 35 U.S.C. 119, the contents of which in its entirety are herein incorporated by reference.

### BACKGROUND

Various example embodiments relate to an image sensor.

An image sensing device is a device that senses an image using an optical sensor. The image sensing device includes an image sensor. One type of the image sensor is a complementary metal oxide semiconductor (CMOS) image sensor. The CMOS image sensor may include a plurality of pixels PX that are two-dimensionally arranged. Each of the pixels PX may include a photosensitive element such as a photodiode (PD). The photodiode may serve to convert incident light into an electrical signal.

In recent years, with the development of the computer industry and the telecommunications industry, demands or expectations for image sensors with improved performance have been increased in various fields, such as digital cameras, camcorders, smartphones, game devices, security cameras, medical micro cameras, robots, vehicles, and the like.

### SUMMARY

Various example embodiments provide an image sensor having improved image quality.

According to some example embodiments, there is provided an image sensor comprising a first sub-pixel comprising a first photoelectric conversion region, a first floating diffusion region, and a first transfer transistor that is configured to transfer charges accumulated in the first photoelectric conversion region to the first floating diffusion region; and a second sub-pixel adjacent to the first sub-pixel, and comprising a second photoelectric conversion region, a second floating diffusion region, and a second transfer transistor that is configured to transfer charges accumulated in the second photoelectric conversion region to the second floating diffusion region. The first sub-pixel may have a larger area than the second sub-pixel, the first photoelectric conversion region may comprise a first sub-region and a second sub-region that is partitioned by a potential level isolation region that is configured to at least partially block movement of charges, and the first transfer transistor may comprise a first sub-transfer transistor configured to transfer charges accumulated in the first sub-region to the first floating diffusion region, and a second sub-transfer transistor configured to transfer charges accumulated in the second sub-region to the first floating diffusion region.

Alternatively or additionally, according to some example embodiments, there is provided an image sensor comprising a substrate comprising a first surface and a second surface opposite to each other; a pixel isolation layer penetrating the substrate from the first surface to the second surface and partitioning a first sub-pixel region and a second sub-pixel region; a first photoelectric conversion region and a first floating diffusion region that are in the first sub-pixel region in the substrate; a second photoelectric conversion region and a second floating diffusion region that are in the second sub-pixel region in the substrate; a potential level isolation region configured to at least partially block movement of charges, the potential level isolation region in the substrate and partitioning the first photoelectric conversion region into a first sub-region and a second sub-region; and a transfer gate on the substrate, the transfer gate comprising a first sub-transfer gate on the first sub-region and configured to control electrical connection between the first sub-region and the first floating diffusion region, a second sub-transfer gate on the second sub-region and configured to control electrical connection between the second sub-region and the first floating diffusion region, and a second transfer gate on the second sub-pixel region and configured to control electrical connection between the second photoelectric conversion region and the second floating diffusion region.

However, example embodiments are not restricted to the one set forth herein. The above and other aspects will become more apparent to one of ordinary skill in the art to which example embodiments pertains by referencing the detailed description of various example embodiments given below.

### BRIEF DESCRIPTION OF THE DRAWINGS

The above and other aspects and features of various embodiments will become more apparent by describing in detail example embodiments thereof with reference to the attached drawings, in which:

FIG. 1 is a block diagram of an image sensing device according to one embodiment.

FIG. 2 is a schematic perspective view illustrating a stacked structure of an image sensor according to some example embodiments.

FIG. 3 is a schematic perspective view illustrating a stacked structure of an image sensor according to some example embodiments.

FIG. 4 is a block diagram of an image sensor according to some example embodiments.

FIG. 5 is a schematic partial layout view of a pixel of an image sensor according to some example embodiments.

FIG. 6 is a layout view of one pixel according to some example embodiments.

FIG. 7 is a cross-sectional view taken along line VII-VII′ of FIG. 6.

FIG. 8 is a cross-sectional view taken along line VIII-VIII′ of FIG. 6.

FIG. 9 is a diagram illustrating a potential level of a first sub-pixel divided by a potential level controller according to some example embodiments.

FIGS. 10 to 13 are diagrams for describing charge transfer during a light sensing process in a pixel according to some example embodiments.

FIGS. 14 and 15 are diagrams for describing charge transfer during a light sensing process in a pixel according to some example embodiments in a high illuminance state.

FIG. 16 is a diagram for describing charge transfer during a light sensing process in a pixel according to some example embodiments in a high illuminance state.

FIG. 17 is a circuit diagram of a pixel according to some example embodiments.

FIG. 18 is an example timing diagram for describing an operation of a pixel, which has the circuit structure of FIG. 17, according to some example embodiments.

FIG. 19 is an example timing diagram for describing an operation of a pixel, which has the circuit structure of FIG. 17, according to some example embodiments.

FIG. 20 is an example timing diagram for describing an operation of a pixel, which has the circuit structure of FIG. 17, according to still some example embodiments.

FIG. 21 is a layout view of one pixel according to some example embodiments.

FIG. 22 is a layout view of one pixel according to still some example embodiments.

FIG. 23 is a circuit diagram of the one pixel of FIG. 22.

FIG. 24 is a layout view of one pixel according to still some example embodiments.

FIG. 25 is a circuit diagram of one pixel of FIG. 24.

FIGS. 26 and 27 are layout views of one pixel according to some example embodiments.

FIG. 28 is a layout view of one pixel according to still some example embodiments.

FIG. 29 is a cross-sectional view taken along line XXIX-XXIX′ of FIG. 28.

FIG. 30 is a cross-sectional view of one pixel according to still some example embodiments.

FIG. 31 is a diagram of a vehicle including an image sensor according to some example embodiments.

### DETAILED DESCRIPTION OF VARIOUS EXAMPLE EMBODIMENTS

Hereinafter, various embodiments will be described with reference to the accompanying drawings.

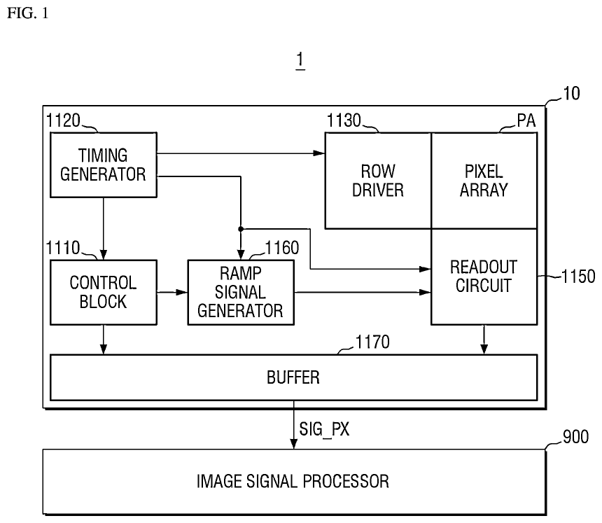

FIG. 1 is a block diagram of an image sensing device according to some example embodiments.

Referring to FIG. 1, an image sensing device 1 may include an image sensor 10 and an image signal processor 900.

The image sensor 10 may generate a pixel signal SIG_PX by sensing an image of a sensing target using light. The generated pixel signal SIG_PX may be or may include, for example, a digital signal, but is not limited thereto, and alternatively or additionally may be or include an analog signal. Also, the pixel signal SIG_PX may include a specific signal voltage and/or a reset voltage. The pixel signal SIG_PX may be provided to an image signal processor 900 to be processed.

The image sensor 10 may include a control register block 1110, a timing generator 1120, a row driver 1130, a pixel array PA, a readout circuit 1150, a ramp signal generator 1160, and a buffer 1170.

The control register block 1110 may control some or all, e.g. the overall operation of the image sensor 10. The control register block 1110 may transmit or directly transmit operation signals to the timing generator 1120, the ramp signal generator 1160 and the buffer 1170.

The timing generator 1120 may generate a reference signal for operation timing of various components of the image sensor 10. The reference signal for operation timing generated by the timing generator 1120 may be transmitted to the row driver 1130, the readout circuit 1150, the ramp signal generator 1160, and the like.

The ramp signal generator 1160 may generate and transmit a ramp signal used in the readout circuit 1150. The readout circuit 1150 may include a correlated double sampler (CDS), a comparator, and/or the like, and the ramp signal generator 1160 may generate and transmit the ramp signal used in the correlated double sampler (CDS), the comparator, and/or the like.

The buffer 1170 may store, e.g. may temporarily store the pixel signal SIG_PX to be provided to the outside, and may serve to transmit the pixel signal SIG_PX to an external memory or an external device. The buffer 1170 may include a memory such as DRAM and/or SRAM.

The pixel array PA may sense an image such as an external image. The pixel array PA may include a plurality of pixels PX (or unit pixels PX). The row driver 1130 may selectively activate a row of the pixel array PA.

The readout circuit 1150 may sample a pixel signal SIG_PX provided from the pixel array PA, compare the pixel signal with the ramp signal, and convert an analog image signal (data) into a digital image signal (data) based on the comparison result.

The image signal processor 900 may receive the pixel signal SIG_PX outputted from the buffer 1170 of the image sensor 10 and process the received pixel signal SIG_PX to be suitable for display. In some example embodiments, the image signal processor 900 may be arranged to be physically separated from the image sensor 10. For example, the image sensor 10 may be mounted on a first chip and the image signal processor 900 may be mounted on a second chip to communicate with each other through a specific, e.g. dynamically determined or predetermined interface. However, example embodiments are not limited thereto, and the image sensor 10 and the image signal processor 900 may be implemented as one package, for example, a multi-chip package (MCP).

As described above, the image sensor may be provided as a single chip. For example, all the functional blocks described above may be implemented in one chip. However, example embodiments are not limited thereto, and the functional blocks may be divided in a plurality of chips to be provided. When the image sensor is provided as a plurality of chips, the chips may be stacked. Hereinafter, a chip stack structure of an example image sensor will be described.

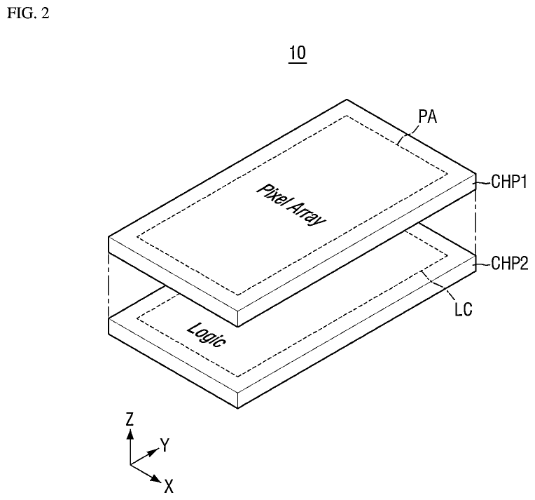

FIG. 2 is a schematic perspective view illustrating a stacked structure of an image sensor according to some example embodiments. FIG. 2 defines a first direction X, a second direction Y, and a third direction Z. The first direction X, the second direction Y, and the third direction Z cross each other. For example, the first direction X, the second direction Y, and the third direction Z may cross each other perpendicularly. The first direction X and the second direction Y may correspond to horizontal directions, and the third direction Z may correspond to a vertical direction. The third direction Z may indicate a thickness direction and/or a depth direction in an element.

Referring to FIG. 2, the image sensor 10 may include an upper chip CHP1 and a lower chip CHP2 that are stacked. The upper chip CHP1 may include the pixel array PA. The lower chip CHP2 may include an analog region having the readout circuit 1150 and a logic region LC. The lower chip CHP2 may be disposed under the upper chip CHP1 and may be electrically connected to the upper chip CHP1. The lower chip CHP2 may receive a pixel signal from the upper chip CHP1, and the logic region LC may receive the corresponding pixel signal.

Logic elements, such as but not limited to standard cells, gates such as NAND/NOR/XOR gates, multiplexers, etc. may be disposed in the logic region LC of the lower chip CHP2. The logic elements may include circuits for processing the pixel signal received from the pixels PX. For example, the logic elements may include the control register block 1110, the timing generator 1120, the row driver 1130, the readout circuit 1150, the ramp signal generator 1160, and the like of FIG. 1.

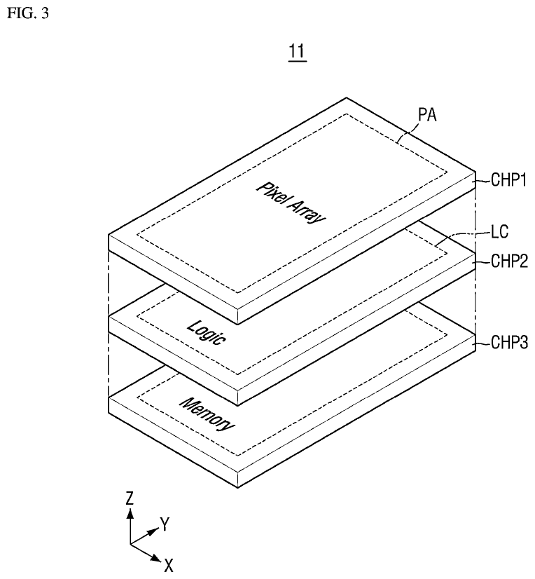

FIG. 3 is a schematic perspective view illustrating a stacked structure of an image sensor according to some example embodiments. Example embodiments of FIG. 3 is different from example embodiments of FIG. 2 in that the image sensor 11 further includes a memory chip CHP3.

For example, as shown in FIG. 3, the image sensor 11 may include the upper chip CHP1, the lower chip CHP2, and the memory chip CHP3. The upper chip CHP1, the lower chip CHP2, and the memory chip CHP3 may be sequentially stacked in the third direction Z. The memory chip CHP3 may be disposed under the lower chip CHP2. The memory chip CHP3 may include a memory. For example, the memory chip CHP3 may include a volatile memory such as DRAM and/or SRAM. The memory chip CHP3 may receive signals from the upper chip CHP1 and the lower chip CHP2 and process the signals through the memory. The image sensor 11 including the memory chip CHP3 may correspond to a three stack image sensor.

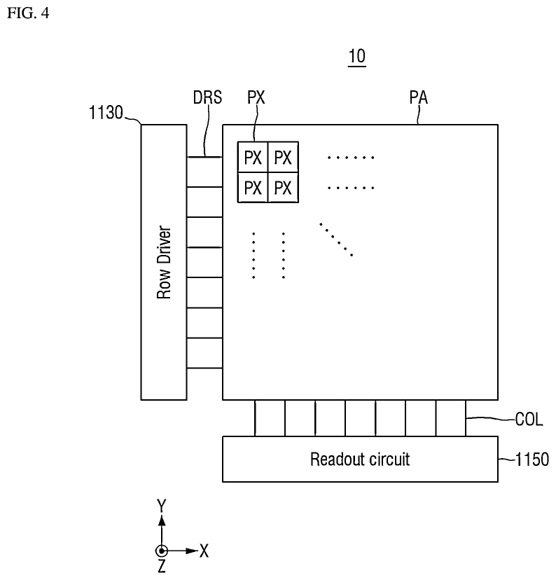

Hereinafter, the pixel array PA of an image sensor will be described in more detail. FIG. 4 is a block diagram of an image sensor according to various example embodiments.

Referring to FIG. 4, the pixel array PA may include a plurality of pixels PX. The pixel PX may be a basic sensing unit that receives light and outputs an image corresponding to one pixel PX. Each pixel PX may include a plurality of sub-pixels. Each sub-pixel may include a photoelectric conversion unit. At least some of the sub-pixels may include a plurality of sub-regions. A detailed description thereof will be given later.

The plurality of pixels PX may be arranged in a two-dimensional matrix having a plurality of rows and a plurality of columns. For simplicity of description, the row refers to an arrangement extending in the first direction X and the column refers to an arrangement extending in the second direction Y in FIG. 4, but the arrangements referred to as the row and the column may be switched around. In addition, although the drawing illustrates a case where the planar shape formed by intersection of rows and columns is a rectangular matrix shape, the matrix shape of the arrangement of the pixels PX may be variously modified. For example, the row or the column may extend in a zigzag and/or honeycomb rather than a straight line, and the pixels PX located in adjacent rows or columns may be alternately arranged. Furthermore, the number of the plurality of rows may be the same as, greater than, or less than the number of the plurality of columns.

A plurality of driving signal lines DRS are connected to the row driver 1130. The plurality of driving signal lines DRS may extend in the row extension direction (i.e., the first direction X). The plurality of driving signal lines DRS may cross an active area of the pixel array PA, which is an effective area where the pixels PX are disposed, in the first direction X. The plurality of driving signal lines DRS may transmit driving signals received from the row driver to the pixels PX. The driving signals may include, for example, a selection signal, a reset signal, a transfer signal, and the like.

In some example embodiments, the pixels PX located in the same row may be connected to the same driving signal line DRS. Further, the pixels PX located in different rows may be connected to different driving signal lines DRS. However, example embodiments are not limited thereto, and the pixels PX located in the same row may be connected to different driving signal lines DRS, or the pixels PX located in two or more rows may be connected to the same driving signal line DRS.

A plurality of output signal lines COL may be connected to the readout circuit 1150. The plurality of output signal lines COL may extend in the column extension direction (i.e., the second direction Y). The plurality of output signal lines COL may cross the active area of the pixel array PA in the second direction Y. The plurality of output signal lines COL may transmit output signals received from the pixels PX to the readout circuit 1150.

In some example embodiments, the pixels PX located in the same column may be connected to the same output signal line COL. Further, the pixels PX located in different columns may be connected to different output signal lines COL. However, example embodiments are not limited thereto, and the pixels PX located in the same column may be connected to different output signal lines COL, or the pixels PX located in two or more columns may be connected to the same output signal line COL.

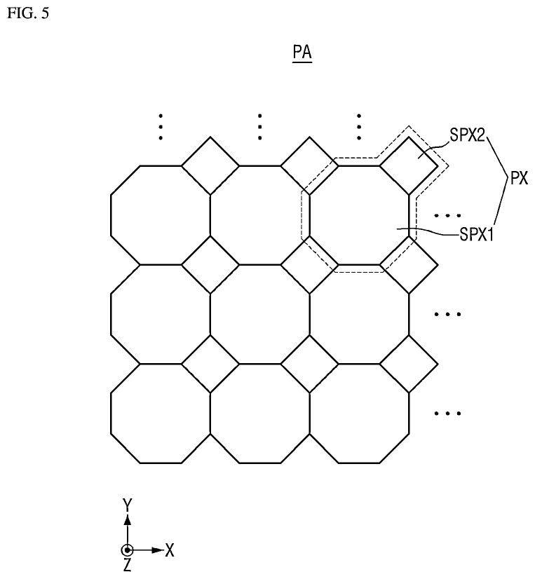

FIG. 5 is a schematic partial layout view of a pixel of an image sensor according to various example embodiments.

Referring to FIG. 5, the pixel PX may include a first sub-pixel SPX1 and a second sub-pixel SPX2. The plurality of sub-pixels SPX1 and SPX2 included in one pixel PX may have, but are not limited thereto, different areas. For example, the first sub-pixel SPX1 may have a larger area than that of the second sub-pixel SPX2.

In some example embodiments, the first sub-pixel SPX1 may have an octagonal shape, and the second sub-pixel SPX2 may have a quadrangular shape. The second sub-pixel SPX2 may be disposed adjacent to one of eight edges of the first sub-pixel SPX1. One edge of the first sub-pixel SPX1 and one edge of the second sub-pixel SPX2 may be in contact with each other, but example embodiments are not limited thereto.

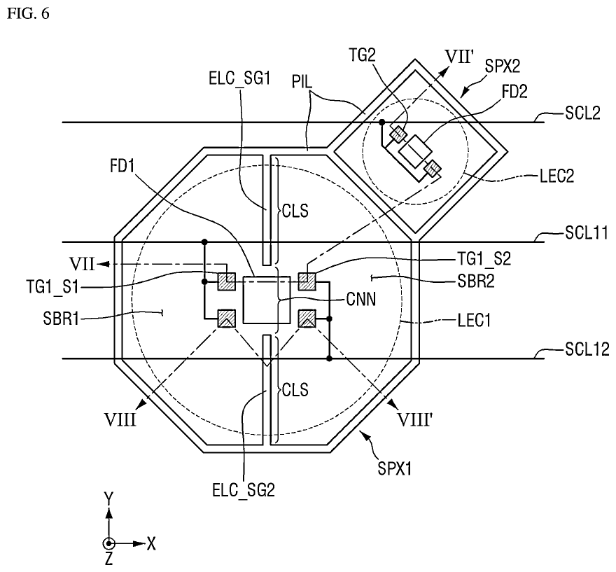

FIG. 6 is a layout view of one pixel according to some example embodiments.

Referring to FIGS. 5 and 6, the pixels PX may be isolated by a pixel isolation layer PIL. In some example embodiments, the pixel isolation layer PIL may include an insulating material and may be a through isolation insulating layer that penetrates, e.g. partially or fully penetrates, a substrate. In addition, the first sub-pixel SPX1 and the second sub-pixel SPX2 in one pixel may also be isolated from each other by the pixel isolation layer PIL. In plan view, the area of the first sub-pixel SPX1 defined by the pixel isolation layer PIL may be larger than the area of the second sub-pixel SPX2.

The first sub-pixel SPX1 and the second sub-pixel SPX2 may include photoelectric conversion regions LEC1 and LEC2, respectively. The first sub-pixel SPX1 may include the first photoelectric conversion region LEC1 completely surrounded by the pixel isolation layer PIL in plan view. The second sub-pixel SPX2 may include the second photoelectric conversion region LEC2 completely surrounded by the pixel isolation layer PIL in plan view. In plan view, the first photoelectric conversion region LEC1 may have a larger area than that of the second photoelectric conversion region LEC2. In plan view, the first photoelectric conversion region LEC1 may have a polygonal shape (such as an octagonal shape), and the second photoelectric conversion element LEC2 may have a rectangular shape (such as a square shape); however, example embodiments ae not limited thereto.

As illustrated, the first photoelectric conversion region LEC1 may be isolated from the second photoelectric conversion region LEC2 by the pixel isolation layer PIL. Accordingly, charges generated in the first photoelectric conversion region LEC1 of the first sub-pixel SPX1 may not be or may be less likely to be mixed with charges generated in the second photoelectric conversion region LEC2 of the second sub-pixel SPX2. As will be described later, since the first sub-pixel SPX1 and the second sub-pixel SPX2 include separate transfer transistors TST, charges generated in the first sub-pixel SPX1 and the second sub-pixel SPX2, which are isolated by the pixel isolation layer PIL in one pixel PX, may be independently sensed.

The first photoelectric conversion region LEC1 of the first sub-pixel SPX1 may include a first sub-region SBR1 and a second sub-region SBR2. The first sub-region SBR1 and the second sub-region SBR2 may be divided by a potential level isolation region or potential level controller ELC.

The potential level controller ELC serves to adjust a potential level of the corresponding location. For example, the potential level controller ELC may lower a potential level of the corresponding location so as to at least partially block or at least partially allow the movement of charges around the potential level controller ELC.

The potential level adjusted by the potential level controller ELC may be maintained higher than that by the pixel isolation layer PIL that blocks the movement of charges. In such a structure, when the amount of charges charged in the first sub-region SBR1 or the second sub-region SBR2 exceeds a specific condition, some charges may move beyond the potential level controller ELC. For example, the potential level controller ELC may block the movement of charges when the charge amount is below a certain level and allow the movement of charges when the charge amount exceeds the certain level. As such, the potential level controller ELC may be or may function as a partial isolation layer or a potential level isolation region. A detailed description thereof will be given later.

The potential level controller ELC for adjusting the potential level may be implemented in various forms. As some example embodiments shown in FIG. 6, the potential level controller ELC may be implemented using the same through isolation insulating layer as the pixel isolation layer PIL.

For example, the potential level controller ELC may have a shape that is branched from the pixel isolation layer PIL located at the edge of the first sub-pixel SPX1. For example, one end of the potential level controller ELC may be connected to the pixel isolation layer PIL. Another end of the potential level controller ELC may be located inside the first photoelectric conversion region LEC1 and may be spaced apart from the pixel isolation layer PIL located at the edge of the first sub-pixel SPX1.

In some example embodiments, referring to FIG. 6, the potential level controller ELC may include a first segment ELC_SG1 and a second segment ELC_SG2. Each of the first segment ELC_SG1 and the second segment ELC_SG2 of the potential level controller ELC may have a shape extending from the pixel isolation layer PIL located at facing edges of the first sub-pixel SPX1, and may or may not be collinear with each other.

For example, two facing edges of the first sub-pixel SPX1 are defined as a first edge and a second edge. The first edge and the second edge may extend in the same direction. For example, the first edge and the second edge of the first sub-pixel SPX1 may extend in the first direction X.

The first segment ELC_SG1 of the potential level controller ELC may be branched from a portion such as the central portion of the pixel isolation layer PIL disposed at the first edge of the first sub-pixel SPX1 and extend toward the second edge thereof in the second direction Y perpendicular to the first direction X. One end of the first segment ELC_SG1 may be placed on the pixel isolation layer PIL disposed on the first edge and while being interconnected therewith.

The second segment ELC_SG2 of the potential level controller ELC may be branched from a portion such as the central portion of the pixel isolation layer PIL disposed at the second edge of the first sub-pixel SPX1 and may extend toward the first edge thereof in the second direction Y. One end of the second segment ELC_SG2 may be placed on the pixel isolation layer PIL disposed on the second edge while being interconnected therewith. For simplicity of description, both the extension direction of the first segment ELC_SG1 and the extension direction of the second segment ELC_SG2 are referred to as the second direction Y, but their extension directions with respect to the branch points may be opposite to each other.

The other end of the first segment ELC_SG1 and the other end of the second segment ELC_SG2 may be spaced apart from each other. In some example embodiments, the other end of the first segment ELC_SG1 and the other end of the second segment ELC_SG2 may not overlap a first floating diffusion region FD1, and may be located at opposite sides with respect to the first floating diffusion region FD1 in the second direction. The second segment ELC_SG2 may be disposed on an extension line of or be collinear with the first segment ELC_SG1, but is not limited thereto.

The first photoelectric conversion region LEC1 may be divided into two sub-regions by the first segment ELC_SG1 and the second segment ELC_SG2 of the potential level controller ELC. For example, the potential level controller ELC may divide the first photoelectric conversion region LEC1, for example, into left and right areas in plan view.

One side of the potential level controller ELC in the first direction X may be referred to as the first sub-region SBR1 of the first photoelectric conversion region LEC1, and another side thereof in the first direction X may be referred to as the second sub-region SBR2 of the first photoelectric conversion region LEC1. The area of the first sub-region SBR1 may be the same as the area of the second sub-region SBR2, but example embodiments are not limited thereto. The first photoelectric conversion region LEC1 may include isolation sections CLS in which the sub-regions SBR1 and SBR2 are physically isolated by the first segment ELC_SG1 and the second segment ELC_SG2, and may further include a connection section CNN in which they are physically connected to each other through a separation region between the first segment ELC_SG1 and the second segment ELC_SG. As such, the first photoelectric conversion region LEC1 includes both the isolation section CLS and the connection section CNN, so that the first photoelectric conversion region LEC1 may have or create a potential level hurdle.

The first sub-pixel SPX1 and the second sub-pixel SPX2 may further include floating diffusion regions FD1 and FD2 in addition to the photoelectric conversion regions LEC1 and LEC2. The first sub-pixel SPX1 may include the first floating diffusion region FD1, and the second sub-pixel SPX2 may include the second floating diffusion region FD2. The first floating diffusion region FD1 may overlap or partially overlap the first photoelectric conversion region LEC1 of the first sub-pixel SPX1, and the second floating diffusion region FD2 may overlap the second photoelectric conversion region LEC2 of the second sub-pixel SPX2, but example embodiments are not limited thereto. The first floating diffusion region FD1 and the second floating diffusion region FD2 may be arranged to be physically spaced apart from each other.

The first sub-pixel SPX1 and the second sub-pixel SPX2 may include transfer gates that transfer charges such as electrons and/or holes, which are generated in the photoelectric conversion regions LEC1 and LEC2, to the floating diffusion regions FD1 and FD2, respectively. The first sub-pixel SPX1 may include a first transfer gate TG1 that transfers charges generated in the first photoelectric conversion region LEC1 to the first floating diffusion region FD1. The second sub-pixel SPX2 may include a second transfer gate TG2 that transfers charges generated in the second photoelectric conversion region LEC2 to the second floating diffusion region FD2.

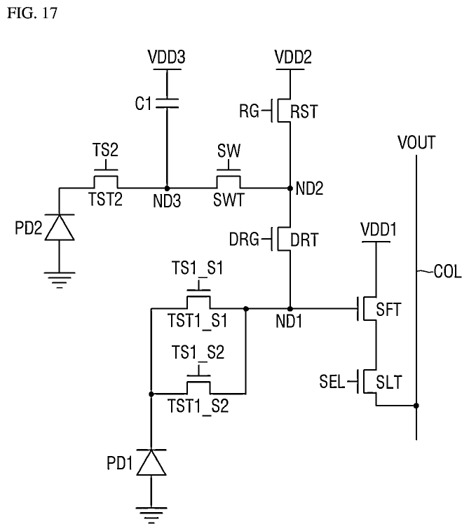

The first transfer gate TG1 may include a first sub-transfer gate TG1_S1 that overlaps the first sub-region SBR1 of the first photoelectric conversion region LEC1 and a second sub-transfer gate TG1_S2 that overlaps the second sub-region SBR2 of the first photoelectric conversion region LEC1. The first sub-transfer gate TG1_S1 of the first transfer gate TG1 may be configured to mainly transfer charges generated in the first sub-region SBR1 to the first floating diffusion region FD1. The second sub-transfer gate TG1_S2 of the first transfer gate TG1 may be configured to mainly transfer charges generated in the second sub-region SBR2 to the first floating diffusion region FD1. The first floating diffusion region FD1 may be connected to one end of a first sub-transfer transistor (see ‘TST1_S1’ in FIG. 17) including the first sub-transfer gate TG1_S1 and one end of a second sub-transfer transistor (see ‘TST2_S2’ in FIG. 17) including the second sub-transfer gate TG1_S2. For example, the first sub-transfer transistor TST1_S1 and the second sub-transfer transistor TST1_S2 may share one floating diffusion region.

The second floating diffusion region FD2 may be connected to one end of a second transfer transistor (see ‘TST2’ in FIG. 17) including the second transfer gate TG2.

Each of the first sub-transfer gate TG1_S1, the second sub-transfer gate TG1_S2, and the second transfer gate TG2 may be configured to receive a separate scan signal (or a transfer signal). For example, the first sub-transfer gate TG1_S1 may be connected to a first sub-transfer line SCL11, which is a first scan line, to receive a first sub-transfer signal TS1_S1. The second sub-transfer gate TG1_S2 may be connected to a second sub-transfer line SCL12, which is a second scan line, to receive a second sub-transfer signal TS1_S2. The second transfer gate TG2 may be connected to a second transfer line SCL2, which is a third scan line, to receive a second transfer signal TS2. Accordingly, the first sub-transfer transistor TST1_S1, the second sub-transfer transistor TST1_S2, and the second transfer transistor TST2 may operate independently and/or at separate timings.

Since the second transfer transistor TST2 connected to the second photoelectric conversion region LEC2, and the first sub-transfer transistor TST1_S1 and the second sub-transfer transistor TST1_S2 connected to the first photoelectric conversion region LEC1 are independently driven, the image sensor may have a wide dynamic range from low illuminance to high illuminance. Alternatively or additionally, as the first sub-transfer transistor TST1_S1 and the second sub-transfer transistor TST1_S2, which are mainly in charge of the respective sub-regions SBR1 and SBR2 of the first photoelectric conversion region LEC1, are independently driven, it is possible to sense the difference in the amounts of incident light to the respective sub-regions SBR1 and SBR2, and implement an auto-focusing function based on the result. This will be described in detail later.

The first photoelectric conversion region LEC1 may overlap the first transfer gate TG1 and the first floating diffusion region FD1. The second photoelectric conversion region LEC2 may overlap the second transfer gate TG2 and the second floating diffusion region FD2. The first sub-transfer gate TG1_S1 may overlap the first sub-region SBR1, but may not overlap the second sub-region SBR2. The second sub-transfer gate TG1_S2 may overlap the second sub-region SBR2 but may not overlap the first sub-region SBR1. The first floating diffusion region FD1 may overlap both the first sub-region SBR1 and the second sub-region SBR2. For example, the first floating diffusion region FD1 may extend from the first sub-region SBR1 to the second sub-region SBR2 beyond the boundary between the first sub-region SBR1 and the second sub-region SBR2. The first sub-transfer gate TG1_S1 and the second sub-transfer gate TG1_S2 may be opposite to each other with the first floating diffusion region FD1 interposed therebetween.

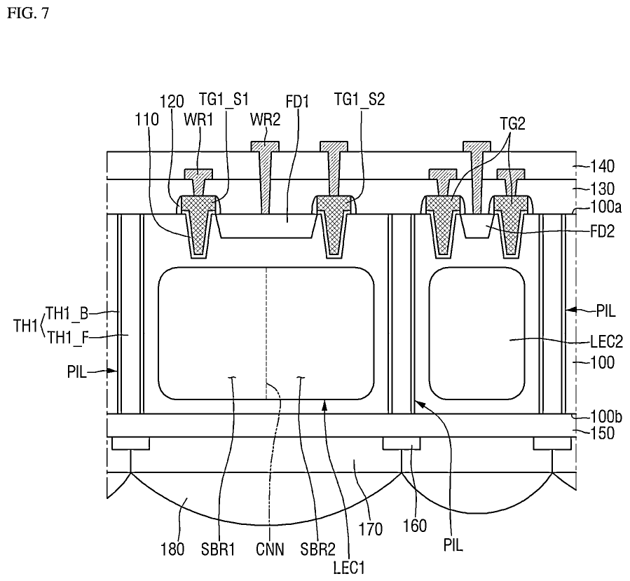

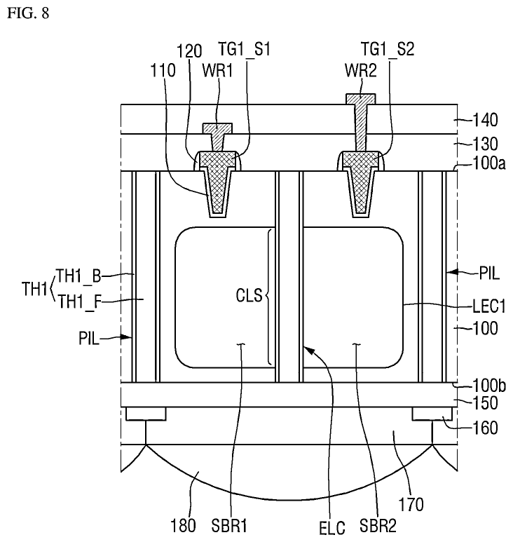

FIG. 7 is a cross-sectional view taken along line VII-VII′ of FIG. 6. FIG. 8 is a cross-sectional view taken along line VIII-VIII′ of FIG. 6.

Referring to FIGS. 6 to 8, the pixel PX included in the image sensor 10 includes the substrate 100. The photoelectric conversion regions LEC1 and LEC2, the floating diffusion regions FD1 and FD2, and a through isolation insulating layer TH1 may be disposed in the substrate 100. The substrate 100 may include the transfer gates TG1 and TG2, a gate insulating layer 110, and a gate spacer 120 thereon.

The substrate 100 may be or may include or be included in a semiconductor substrate. For example, the substrate 100 may be or include a bulk silicon or silicon-on-insulator (SOI) substrate. The substrate 100 may be or include a silicon substrate, or may include other materials such as one or more of silicon germanium, indium antimonide, lead tellurium compound, indium arsenide, indium phosphide, gallium arsenide, or gallium antimonide. Alternatively or additionally, the substrate 100 may have a homogeneous and/or heterogeneous epitaxial layer formed on a base substrate.

The substrate 100 may include a first surface 100a and a second surface 100b opposite to each other. In the following example embodiments, in some cases, the first surface 100a may be referred to as a front side of the substrate 100, and the second surface 100b may be referred to as a back side of the substrate 100. The second surface 100b of the substrate 100 may be a photo-receiving surface on which light is incident. For example, the image sensor according to some example embodiments may be or include or be included in a backside illuminated (BSI) image sensor.

In some example embodiments, the substrate 100 may have a first conductivity type. For example, the substrate 100 may include a p-type impurity (e.g., boron (B)). Although the description is directed to the case where the first conductivity type is a p-type in the following embodiments, this is only by example and the first conductivity type may be an n-type.

The photoelectric conversion regions LEC1 and LEC2 may be disposed in the substrate 100. The photoelectric conversion regions LEC1 and LEC2 may be located in a space between the first surface 100a and the second surface 100b. Each of the photoelectric conversion regions LEC1 and LEC2 may be disposed to be spaced apart from the first surface 100a and the second surface 100b by specific, dynamically determined or predetermined distances.

The photoelectric conversion regions LEC1 and LEC2 may have a second conductivity type different from the first conductivity type. Although the description is directed to the case in which the second conductivity type is an n-type, this is only by example, and the second conductivity type may be a p-type. The photoelectric conversion regions LEC1 and LEC2 may be formed by ion-implanting, for example, n-type impurities (e.g., phosphorus (P) and/or arsenic (As)) into the p-type substrate 100.

The floating diffusion regions FD1 and FD2 may be disposed in the substrate 100. The floating diffusion regions FD1 and FD2 may be disposed adjacent to the first surface 100a of the substrate 100. The first floating diffusion region FD1 may overlap the first photoelectric conversion region LEC1 in the vertical direction (third direction Z), and the second floating diffusion region FD2 may overlap the second photoelectric conversion region LEC2 in the vertical direction (third direction Z). The first and second floating diffusion regions FD1 and FD2 may be spaced apart from the first and second photoelectric conversion regions LEC1 and LEC2 in the third direction Z (i.e., thickness direction), but example embodiments are not limited thereto.

The floating diffusion regions FD1 and FD2 may have the second conductivity type. For example, the floating diffusion regions FD1 and FD2 may be or include first impurity regions formed by ion-implanting n-type impurities into the p-type substrate 100.

In some example embodiments, the floating diffusion regions FD1 and FD2 may have the second conductivity type with a higher impurity concentration than that of the photoelectric conversion region LEC. For example, the floating diffusion region FD may be formed by ion-implanting a high concentration of n-type impurities (n+) into the p-type substrate 100.

The through isolation insulating layer THI may be disposed in the substrate 100. The through isolation insulating layer THI may serve as an element isolation layer. That is, the through isolation insulating layer THI may block the drift of charges between the isolated regions.

The through isolation insulating layer THI may include the pixel isolation layer PIL disposed at the boundary between the sub-pixels SPX1 and SPX2 and the potential level controller ELC disposed at the boundary between the first sub-region SBR1 and the second sub-region SBR2 in plan view.

The pixel isolation layer PIL may be continuously disposed along the boundary between the sub-pixels SPX1 and SPX2 in plan view. In plan view, the pixel isolation layer PIL may have a lattice shape. The potential level controller ELC may include the first segment ELC_SG1 and the second segment ELC_SG2 as described above, and may partially expose the boundary between the first sub-region SBR1 and the second sub-region SBR2 of the first photoelectric conversion region LEC1 in plan view such that the first sub-region SBR1 and the second sub-region SBR2 are not completely isolated from each other.

The through isolation insulating layer THI may extend from the first surface 100a to the second surface 100b of the substrate 100. In the extension direction of the through isolation insulating layer THI, one end of the through isolation insulating layer THI may be placed on the first surface 100a of the substrate 100, and the other end thereof may be placed on the second surface 100b of the substrate 100. For example, the through isolation insulating layer THI may have a shape partially or wholly penetrating the substrate 100 in the third direction Z.

The through isolation insulating layer THI may be formed by removing a constituent material of the substrate 100 and then filling a space after the removal with an isolation layer material.

In some example embodiments, the through isolation insulating layer THI may include a barrier layer THI_B and a filling layer THI_F.

The barrier layer THI_B may form the sidewall of the through isolation insulating layer THI. The barrier layer THI_B may include a high-k insulating material, but is not limited thereto. The barrier layer THI_B may define a space (such as a dynamically determined or predetermined space), and the filling layer THI_F may be disposed in the space. The filling layer THI_F may include a material having excellent gap-fill performance, for example, polysilicon, but is not limited thereto.

The transfer gates TG1 and TG2 are disposed on the first surface 100a of the substrate 100. As described above, the transfer gates TG1 and TG2 may include the first sub-transfer gate TG1_S1, the second sub-transfer gate TG1_S2, and the second transfer gate TG2, which have substantially the same structure. For example, as shown in the drawings, each of the first sub-transfer gate TG1_S1, the second sub-transfer gate TG1_S2, and the second transfer gate TG2 may have a vertical multi-type gate structure, which is partially buried in the substrate 100 and has a plurality of gate electrodes, for example, a vertical double gate structure in plan view. In addition, although not shown, the image sensor 10 may further include gates such as a reset gate (‘RG’ in FIG. 17), a switch gate (‘SW’ in FIG. 17), and a connection control gate (‘DRG’ in FIG. 17). These gates may also have substantially the same structure as the shown transfer gates TG1 and TG2. However, example embodiments are not limited thereto, and the gates may have different structures. Examples of the different structures may include a horizontal gate structure that is not buried in the substrate, a single gate structure having only one gate, and the like. A horizontal/vertical gate structure and a single/multi-type gate may be applied in combination with each other.

The substrate 100 may include a trench accommodating the transfer gates TG1 and TG2.

The transfer gates TG1 and TG2 may include, for example, at least one of polysilicon doped with impurities, metal silicides such as cobalt silicide, metal nitrides such as titanium nitride, or metals such as tungsten, copper or aluminum.

The gate insulating layer 110 may be disposed on the first surface 100a of the substrate 100. The gate insulating layer 110 may be disposed between the transfer gate TG and the substrate 100. The gate insulating layer 110 may be formed not only on the first surface 100a of the substrate 100, but also on or in the trench of the substrate 100. The gate insulating layer 110 may include, for example, at least one of silicon nitride (SiN), silicon oxynitride (SiON), silicon carbonitride (SiCN), and a low-k material having a lower dielectric constant than silicon oxide, or a high-k material having a higher dielectric constant than silicon oxide, but is not limited thereto.

The gate spacers 120 may be disposed on the side surfaces of the transfer gates TG1 and TG2. The gate spacer 120 may include, for example, at least one of silicon nitride, silicon oxynitride, silicon carbonitride (SiCN), silicon oxycarbonitride (SiOCN), silicon boron nitride (SiBN), silicon oxyboron nitride (SiOBN), silicon oxycarbide (SiOC), or a combination thereof. The gate spacer 120 may be omitted.

A first interlayer insulating layer 130 may be disposed on the transfer gates TG1 and TG2. A first wiring layer WR1 may be disposed on the first interlayer insulating layer 130. In some example embodiments, the image sensor 10 may further include a second interlayer insulating layer 140 on the first wiring layer WR1 and a second wiring layer WR2 on the second interlayer insulating layer 140. In the cross-sectional views of FIGS. 7 and 8, contacts and the wirings WR1 and WR2 are additionally illustrated irrespective of the plan view of FIG. 6 for simplicity of description. In this case, the illustration of the contacts and the wiring layers WR1 and WR2 is merely for describing the stacked relationship therebetween, and does not necessarily mean that they are arranged at positions coincident with cut line of FIG. 6.

Each of the first interlayer insulating layer 130 and the second interlayer insulating layer 140 may include, for example, at least one of silicon oxide, silicon nitride, silicon oxynitride, a low-k material, or a combination thereof.

Each of the first wiring layer WR1 and the second wiring layer WR2 may include one or more of aluminum (Al), copper (Cu), tungsten (W), cobalt (Co), ruthenium (Ru), or the like, but is limited thereto.

Each of the wiring layers WR1 and WR2 may include a plurality of wirings or electrodes, and at least one of the wirings WR1 and WR2 may be connected to the transfer gates TG1 and TG2 and the floating diffusion regions FD1 and FD2 with through vias or contacts that penetrate the interlayer insulating layers 130 and 140.

Each of the first sub-transfer line SCL11 that transfers the first sub-transfer signal TS1_S1 to the first sub-transfer gate TG1_S1, the second sub-transfer line SCL12 that transfers the second sub-transfer signal TS1_S2 to the second sub-transfer gate TG1_S2, and the second transfer line SCL2 that transfers the second transfer signal TS2 to the second transfer gate TG2 may be formed of one of the first wiring layer WR1 and the second wiring layer WR2. The drawings illustrates the case in which a via electrode connected to the first sub-transfer line SCL11 and the second transfer line SCL2 is made of the first wiring layer WR1, and a via electrode connected to the second sub-transfer line SCL12 and the floating diffusion regions FD1 and FD2 is made of the second wiring layer WR2, but the via electrodes or wirings may be made of a combination of various other wiring layers. For example, the via electrodes may be made of only one wiring layer, or the via electrodes may be made of three or more wiring layers.

The image sensor 10 may further include a color filter 170, a micro lens 180, a grid pattern 160, and a passivation layer 150 that are disposed on the second surface 100b of the substrate 100.

Specifically, the passivation layer 150 may be disposed on the second surface 100b of the substrate. The passivation layer 150 may include, for example, a high-k insulating material. In addition, the passivation layer 150 may include an amorphous crystal structure.

Although the drawings illustrates the case in which the passivation layer 150 is made of one layer, example embodiments are not limited thereto. In some example embodiments, the passivation layer 150 may further include a planarization layer and/or an anti-reflection layer. In this case, the planarization layer may include, for example, at least one of a silicon oxide-based material, a silicon nitride-based material, a resin, or a combination thereof. The anti-reflection layer may include a high dielectric constant material, for example, hafnium oxide (HfO₂), but the technical spirit of example embodiments are not limited thereto.

The color filter 170 may be disposed on the passivation layer 150. The color filter 170 may be arranged to correspond to each unit pixel PX. For example, the color filters 170 may be arranged two-dimensionally (e.g., in a matrix form) in a plane defined by the first direction X and the second direction Y. The color filters 170 may be arranged in a Bayer pattern; however, example embodiments are not limited thereto.

The color filter 170 may include a red, green, or blue color filter disposed for each pixel PX. In addition, the color filter 170 may include a yellow filter, a magenta filter, and a cyan filter, and may further include a white filter.

The color filters 170 having the same color may be disposed in the sub-pixels SPX1 and SPX2 included in one pixel PX. The color filter 170 applied to each of the sub-pixels SPX1 and SPX2 included in one pixel PX may be integrally formed regardless of division of the sub-pixels SPX1 and SPX2, or may be applied separately to each of the sub-pixels SPX1 and SPX2.

The grid pattern 160 may be formed in a grid shape above the second surface 100b of the substrate 100 to surround each pixel PX and each of the sub-pixels SPX1 and SPX2 included therein. For example, the grid pattern 160 may be disposed between the color filters 170 on the passivation layer 150. The grid pattern 160 may serve to provide more incident light to the photoelectric conversion regions LEC1 and LEC2 by reflecting light incident obliquely.

The micro lens 180 may be disposed on the color filter 170. The micro lenses 180 may be arranged to correspond to the respective sub-pixels SPX1 and SPX2.

The micro lenses 180 may be disposed to cover the photoelectric conversion regions LEC1 and LEC2, respectively. Each of the micro lenses 180 may have a convex surface to condense the incident light toward the photoelectric conversion regions LEC1 and LEC2. The micro lens 180 may include a photoresist material or a thermosetting resin, but is not limited thereto.

Hereinafter, a description will be made regarding a method of sensing light for each region by dividing the first sub-region SBR1 and the second sub-region SBR2 of the first photoelectric conversion region LEC1.

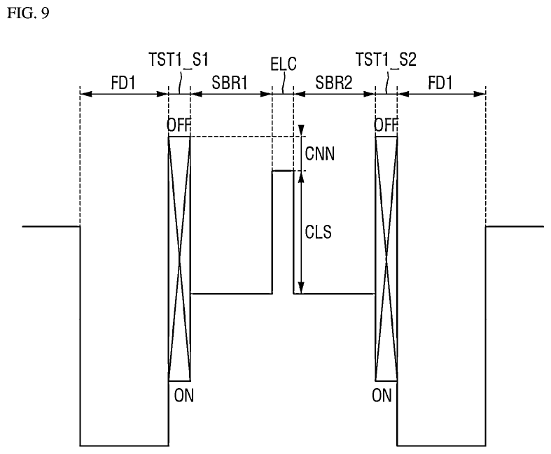

FIG. 9 is a diagram, e.g. a band or Fermi-level diagram, illustrating a potential level of a first sub-pixel divided by a potential level controller according to some example embodiments. FIG. 9 shows potential levels of the first sub-region SBR1, the potential level controller ELC, and the second sub-region SBR2, channel regions of the sub-transfer transistors TST1_S1 and TST1_S2, and the first floating diffusion region FD1 of the first photodiode PD1 (corresponding to the first photoelectric conversion region LEC1). For simplicity of description, although the first floating diffusion regions FD1 are shown on both the left and right sides, the first floating diffusion region FD1 on the left side and the first floating diffusion region FD1 on the right side both indicate the potential level of the same first floating diffusion region FD1. The potential diagram shown in FIG. 9 is drawn based on electrons, and it is interpreted that the potential level becomes higher toward the lower side of the drawing.

Referring to FIG. 9, the first sub-region SBR1 and the second sub-region SBR2 of the first photodiode may have the same (maximum) potential. The first floating diffusion region FD1 may have a (maximum) potential greater than that of the sub-regions SBR1 and SBR2. The channel regions of the sub-transfer transistors TST1_S1 and TST1_S2 are respectively interposed between the first floating diffusion region FD1 and the sub-regions SBR1 and SBR2. In a state in which each of the sub-transfer transistors TST1_S1 and TST1_S2 is turned off, the channel regions have a low level shut-off voltage, and thus the cannel regions may act as potential barriers between the sub-regions SBR1 and SBR2 and the first floating diffusion region FD1. When the transfer transistors TST1_S1 and TST1_S2 are turned on, the potential level of the channel regions increases and the potential barriers therebetween may be released.

The potential level controller ELC is interposed between the first sub-region SBR1 and the second sub-region SBR2. As described above, when the potential level controller ELC is formed through the through isolation insulating layer THI, the potential level controller ELC may act as a potential barrier or a potential barrier region. However, as the through isolation insulating layer THI does not completely partition the first sub-region SBR1 and the second sub-region SBR2 to allow the physical connection between the first sub-region SBR1 and the second sub-region SBR2 in some sections, charge transfer between the first sub-region SBR1 and the second sub-region SBR2 may not be completely cut off and some charges may be allowed to move therebetween. For example, the potential level controller ELC partially acts as a partial potential barrier (see ‘CLS’), but does not form a complete potential barrier (see ‘CNN’).

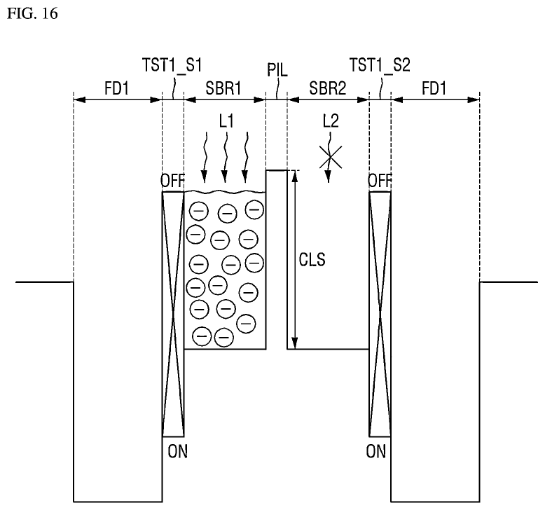

The potential level controller ELC has a higher potential level compared to example embodiments of FIG. 16 that illustrates the case in which the through isolation insulating layer THI completely partitions the first sub-region SBR1 and the second sub-region SBR2. Specifically, the potential level of the potential level controller ELC according to some example embodiments are between the maximum potential of the sub-regions SBR1 and SBR2 and the shut-off voltage of the sub-transfer transistors TST1_S1 and TST1_S2, as shown in FIG. 9. For example, the potential level of the potential level controller ELC may be lower than the maximum potential of the sub-regions SBR1 and SBR2 and may be higher than the shut-off voltage. For example, the potential level of the potential level controller ELC based on the shut-off voltage may be 0.1 to 0.5 times or 0.2 to 0.4 times the maximum potential of the sub-regions SBR1 and SBR2, but example embodiments are not limited thereto.

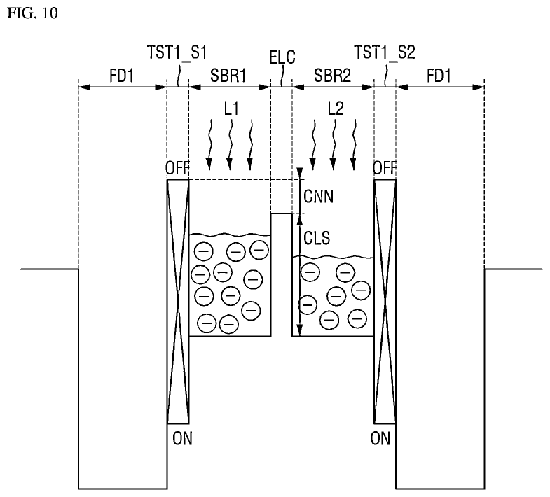

FIGS. 10 to 13 are diagrams for describing charge transfer during a light sensing process in a pixel according to some example embodiments.

Referring to FIG. 10, the adjacent first sub-region SBR1 and second sub-region SBR2 may be exposed to different amounts of lights L1 and L2 according to a distance from a subject, an incident angle of light, and the like. In each of the sub-regions SBR1 and SBR2, a charge-hole pair or an electron-hole pair may be generated proportional to the received light. In a state in which the first sub-transfer transistor TST1_S1 and the second sub-transfer transistor TST1_S2 are turned off, charges or electrons accumulated in each of the sub-regions SBR1 and SBR2 may be blocked from moving to the first floating diffusion region FD1. In addition, since a potential barrier by the potential level controller ELC is also formed between the first sub-region SBR1 and the second sub-region SBR2, the movement of charges may be blocked even between the first sub-region SBR1 and the second sub-region SBR2 when the amount of generated charges does not exceed the potential barrier by the potential level controller ELC. Accordingly, charges generated in the first sub-region SBR1 may be accumulated in the first sub-region SBR1, and charges generated in the second sub-region SBR2 may be accumulated in the second sub-region SBR2.

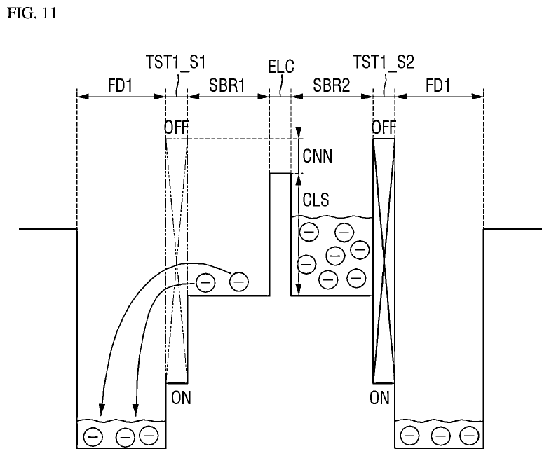

Subsequently, as shown in FIG. 11, when the first sub-transfer transistor TST1_S1 is turned on, the potential barrier between the first floating diffusion region FD1 and the first sub-region SBR1 is removed, and thus the charges or electrons accumulated in the first sub-region SBR1 may move toward the first floating diffusion region FD1. At this time, if the second sub-transfer transistor TST1_S2 maintains the turned-off state, the charges accumulated in the second sub-region SBR2 may not move toward the first sub-region SBR1 or the first floating diffusion region FD1 and may remain in the second sub-region SBR2 as it is. Accordingly, the amount of charges (e.g., electrons) generated in the first sub-region SBR1 may be measured by sensing the charges moved to the first floating diffusion region FD1.

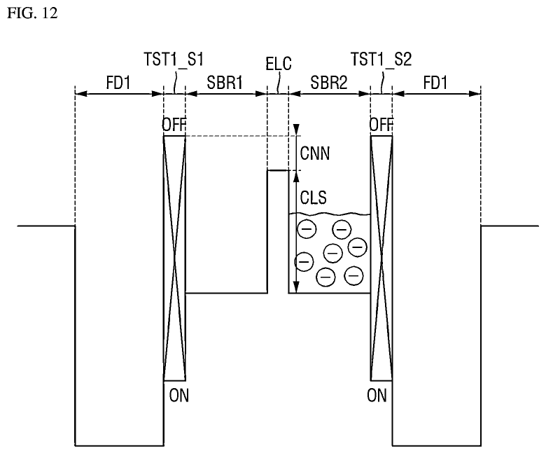

Referring to FIG. 12, after sensing with respect to the first floating diffusion region FD1 is completed, the first floating diffusion region FD1 is reset. For simplicity of description, although the case, in which the first floating diffusion region FD1 is initialized after resetting, is illustrated for example, the first floating diffusion region FD1 may be reset to a specific reset voltage. The first sub-transfer gate TG1_S1 may be turned off before or after the reset operation.

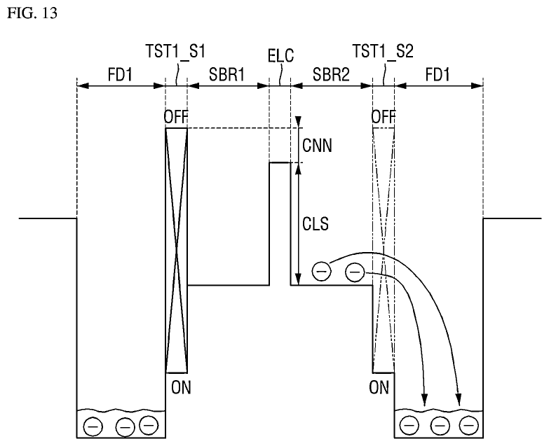

Referring to FIG. 13, the potential barrier between the second sub-region SBR2 and the first floating diffusion region FD1 is removed by turning on the second sub-transfer transistor TST1_S2 so that the charges accumulated in the second sub-region SBR2 may be moved toward the first floating diffusion region FD1. In this step, if the first floating diffusion region FD1 is sensed, the amount of charges generated in the second sub-region SBR2 may be measured.

As described above, the charge amount of each of the first sub-region SBR1 and the second sub-region SBR2 may be measured by disposing the potential level controller ELC between the first sub-region SBR1 and the second sub-region SBR2 of the first photoelectric conversion region LEC1, and disposing the sub-transfer transistors TST1_S1 and TST1_S2 in the respective first and second sub-regions SBR1 and SBR2. As such, the charge amount of the first sub-region SBR1 and the charge amount of the second sub-region SBR2, which are separately measured, may be used to measure the distance to the subject, and focusing on the subject may be adjusted by using it. For example, the image sensor 10 according to some example embodiments may support auto-focusing. Alternatively or additionally, since the lights L1 and L2 incident on the first sub-region SBR1 and the second sub-region SBR2 can be measured without loss of light reception due to masking, not only can the measurement efficiency be increased, but also more accurate illuminance measurement may be possible.

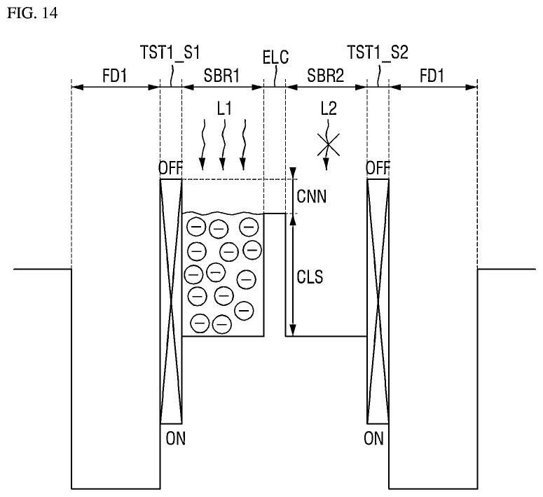

Additionally or alternatively, by providing the potential level controller ELC, additional charges may be generated even after generating a maximum amount of charges that can be accumulated in one sub-region, so that a wider range of illuminance may be precisely measured. For more detailed descriptions thereof, reference is made to FIGS. 14 to 16.

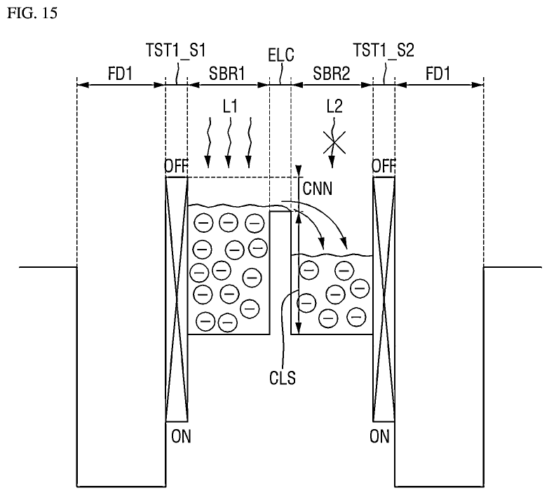

FIGS. 14 and 15 are diagrams for describing charge transfer during a light sensing process in a pixel according to some example embodiments in a high illuminance state. FIG. 16 is a diagram for describing charge transfer during a light sensing process in a pixel according to some example embodiments in a high illuminance state.

First, referring to FIG. 14, the first sub-region SBR1 and the second sub-region SBR2 may be exposed to different amounts of lights L1 and L2 as described above. FIG. 14 illustrates, in a particular fashion, a case in which the light L1 enters only the first sub-region SBR1 and the light L2 does not enter the second sub-region SBR2, but the following description will be also applicable to some example embodiments in which the first sub-region SBR1 receives a greater amount of light than the second sub-region SBR2.

When the light L1 is incident on the first sub-region SBR1, charges are generated in the first sub-region SBR1 and accumulated therein within a capacity limit thereof. The charge capacity that the first sub-region SBR1 may accumulate alone may be proportional to the volume (or, a width in the drawings) of the first sub-region SBR1 and a difference (or, a height of the potential level controller ELC in the drawings), which is obtained by subtracting the potential of the potential level controller ELC from the maximum potential of the first sub-region SBR1. When the first sub-region SBR1 is placed in a high illuminance environment, charges may be generated actively in the first sub-region SBR1, and may reach a maximum allowable accumulation capacity before a sensing time point.

When light is continuously incident on the first sub-region SBR1 even after the charges are generated up to the maximum allowable accumulation capacity, additional charges may be generated. As illustrated in FIG. 15, the additionally generated charges may move to the second sub-region SBR2 through the connection section CNN beyond the potential level controller ELC to be accumulated in the second sub-region SBR2. This action may be contrasted with a case in which the first sub-region SBR1 and the second sub-region SBR2 are completely isolated by the pixel isolation layer PIL as shown in FIG. 16.

FIG. 16 is a diagram illustrating a light sensing process in the case in which the first sub-region SBR1 and the second sub-region SBR2 are completely isolated by the pixel isolation layer PIL without the connection section CNN.

Referring to FIG. 16, when the first sub-region SBR1 and the second sub-region SBR2 are completely blocked from each other by the pixel isolation layer PIL, the pixel isolation layer PIL has a lower potential level. Accordingly, charges generated in the first sub-region SBR1 hardly move to the second sub-region SBR2 due to a potential barrier by the pixel isolation layer PIL. In example embodiments of FIG. 16, when a large amount of light L1 is incident on the first sub-region SBR1 in a high illuminance environment, it is difficult to accumulate information on light above a specific or dynamically determined or predetermined amount. On the other hand, in some example embodiments, as shown in FIG. 15, even when the first sub-region SBR1 generates charges exceeding the maximum allowable accumulation capacity, the generated charges may be accumulated using the second sub-region SBR2 so that information on a greater amount of light may be sensed.

Hereinafter, an example pixel circuit and an operation thereof according to some example embodiments will be described.

FIG. 17 is a circuit diagram of a pixel according to some example embodiments.

Referring to FIG. 17, the pixel circuit includes the first photodiode PD1, a second photodiode PD2, a plurality of transistors, and a capacitor C1. The plurality of transistors may include the transfer transistor TST, a source follower transistor SFT, a selection transistor SLT, a reset transistor RST, a connection transistor DRT, and a switching transistor SWT. Each of the transfer transistor TST, the source follower transistor SFT, the selection transistor SLT, the reset transistor RST, the connection transistor DRT, and the switching transistor SWT may have the same electrical and/or physical properties; however, example embodiments are not limited thereto.

The first sub-pixel SPX1 may include the first photodiode PD1 and a first transfer transistor TST1. The second sub-pixel SPX2 may include the second photodiode PD2 and a second transfer transistor TST2. The first transfer transistor TST1 may include the first sub-transfer transistor TST1_S1 and the second sub-transfer transistor TST1_S2 that are connected in parallel between the first photodiode PD1 and a first node ND1.

The first photodiode PD1 may correspond to the first photoelectric conversion region LEC1, and the second photodiode PD2 may correspond to the second photoelectric conversion region LEC2. In plan view, the first photodiode PD1, which includes the first photoelectric conversion region LEC1 having a relatively large area, may be referred to as a large photodiode, and the second photodiode PD2, which includes the relatively small second photoelectric conversion region LEC2, may be referred to as a small photodiode.

The first sub-pixel SPX1 and the second sub-pixel SPX2 may share one source follower transistor SFT, one selection transistor SLT, and one reset transistor RST.

More specifically, the first sub-transfer transistor TST1_S1 and the second sub-transfer transistor TST1_S2 are respectively disposed between the first photodiode PD1 and the first node ND1. The first node ND1 may be connected to the first floating diffusion region FD1 or may itself be the first floating diffusion region FD1. The first sub-transfer gate TG1_S1, which is a gate of the first sub-transfer transistor TST1_S1, may be connected to the first sub-transfer line SCL11 to receive the first sub-transfer signal TS1_S1. The second sub-transfer gate TG1_S2, which is a gate of the second sub-transfer transistor TST1_S2, may be connected to the second sub-transfer line SCL12 to receive the second sub-transfer signal TS1_S2 that is different from the first sub-transfer signal TS1_S1.

The source follower transistor SFT is connected between an output signal line COL and a first power voltage line that provides a first power voltage VDD1. The gate of the source follower transistor SFT is connected to the first node ND1 connected to the first floating diffusion region FD1.

The selection transistor SLT is disposed between the source follower transistor SFT and the output signal line COL. The gate of the selection transistor SLT may be connected to a selection line of the corresponding row to receive a selection signal SEL.

The connection transistor DRT and the reset transistor RST are disposed between the first node ND1 and a second power voltage line that provides a second power voltage VDD2. A second node ND2 is defined between the connection transistor DRT and the reset transistor RST.

The connection transistor DRT is disposed between the first node ND1 and the second node ND2. The gate of the connection transistor DRT is connected to a connection signal line. The connection transistor DRT may serve to connect the first node ND1 and the second node ND2 to each other according to a connection control signal DRG provided from the connection signal line.

The reset transistor RST is disposed between the second power voltage line and the second node ND2. The gate of the reset transistor RST may be connected to a reset line to receive a reset signal RG.

The second transfer transistor TST2 and the switching transistor SWT are disposed between the second photodiode PD2 and the second node ND2. A third node ND3 is defined between the second transfer transistor TST2 and the switching transistor SWT.

The second transfer transistor TST2 is connected between the second photodiode PD2 and the third node ND3. The third node ND3 may be connected to the second floating diffusion region FD2 or may itself be the second floating diffusion region FD2. The gate of the second transfer transistor TST2 may be connected to the second transfer line SCL2. The second transfer signal TS2, which is a scan signal different from the first sub-transfer signal TS1_S1 and the second sub-transfer signal TS1_S2, may be applied to the second transfer line SCL2. Accordingly, the first sub-transfer transistor TST1_S1, the second sub-transfer transistor TST1_S2, and the second transfer transistor TST2 may be turned on or off at different time points.

The switching transistor SWT is disposed between the third node ND3 and the second node ND2. The gate of the switching transistor SWT is connected to a switch control line. The switching transistor SWT may serve to connect the third node ND3 and the second node ND2 to each other according to a switch control signal SW applied through the switch control line.

The capacitor C1 is disposed between the third node ND3 and a third power voltage line that provides a third power voltage VDD3. The capacitor C1 may serve to store charges overflowing from the second photodiode PD2. The capacitor C1 may be or may include a metal capacitor whose one electrode and the other electrode are both made of metal, but is not limited thereto.

The above-described first power voltage VDD1, second power voltage VDD2, and third power voltage VDD3 may all be different voltages, but are not limited thereto. Two or all of them may be the same voltage.

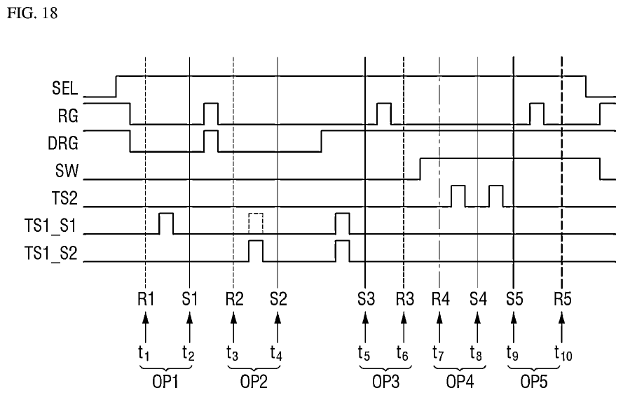

FIG. 18 is an example timing diagram for describing an operation of a pixel, which has the circuit structure of FIG. 17, according to some example embodiments. FIG. 18 illustrates timings of signals applied to one pixel PX located in a row that is a readout target at a corresponding time point. At the same time point, signals different from the illustrated example may be applied to pixels PX corresponding to other rows that are not selected as the readout target. For example, signal waveforms, which appear before or after five operations OP1, OP2, OP3, OP4, and OP5 of FIG. 18, may be applied to the pixels PX corresponding to other rows that are not selected as the readout target.

In the timing diagram of FIG. 18, waveforms of the selection signal SEL, the reset signal RG, the connection control signal DRG, the switch control signal SW, the second transfer signal TS2, the first sub-transfer signal TS1_S1, and the second sub-transfer signal TS1_S2 are sequentially shown. Each signal waveform swings between a high level voltage and a low level voltage. The high level voltage may be a turn-on signal for turning on a transistor to be applied, and the low level voltage may be a turn-off signal for turning off a transistor to be applied.

Referring to FIGS. 17 and 18, readout of the pixel PX may include five operations. Specifically, the readout of the pixel PX may include the first operation OP1, the second operation OP2, the third operation OP3, the fourth operation OP4, and the fifth operation OP5 that are sequentially performed in temporal order. Each of the operations may include signal operations S1, S2, S3, S4, and S5, and may further include reset operations R1, R2, R3, R4, and R5. In one operation, the reset operation may be performed before or after the signal operation. The reset operation may be omitted in some operations. During the five operations, the selection signal SEL maintains high level.

During the time before the readout, that is, during the time before the first operation OP1, the selection signal SEL, the switch control signal SW, the second transfer signal TS2, the first sub-transfer signal TS1_S1, and the second sub-transfer signal TS1_S2 maintain low level, and the reset signal RG and the connection control signal DRG maintain high level.

The first operation OP1 may include the first reset operation R1 and the first signal operation S1. For example, after the first reset operation R1 is first performed at a first time t1, the first signal operation S1 may be performed at a second time t2.

Specifically, until the first time t1 at which the first reset operation R1 is performed, the selection signal SEL is changed from low level to high level, and the reset signal RG and the connection control signal DRG are changed from high level to low level. Charges accumulated in the first node ND1 may be converted into a first reset voltage VR1 through the source follower transistor SFT and outputted during the first reset operation R1.

Subsequently, the first signal operation S1 may be performed at the second time t2. During a time period between the first time t1 and the second time t2, the first sub-transfer signal TS1_S1 may be changed from low level to high level and then changed back to low level. While the first sub-transfer signal TS1_S1 maintains high level, the first sub-transfer transistor TST1_S1 may be turned on for a time (such as a dynamically determined, or alternatively predetermined time) and then turned off. While the first sub-transfer transistor TST1_S1 is turned on, the first node ND1 may be connected to the first photodiode PD1. Through this, charges stored in the first sub-region SBR1 of the first photodiode PD1 may be transferred to the first node ND1 (i.e., the first floating diffusion region FD1). The charges transferred to the first node ND1 may be converted into a first signal voltage VS1 by the source follower transistor SFT and outputted. The first signal voltage VS1 may mainly reflect charge data generated by the first sub-region SBR1 of the first photodiode PD1.

Following the first operation OP1, the second operation OP2 may be performed. The second operation OP2 may include the second reset operation R2 and the second signal operation S2. After the second reset operation R2 is first performed at a third time t3, the second signal operation S2 may be performed at a fourth time t4.

Specifically, during a time period between the second time t2 and the third time t3, the reset signal RG and the connection control signal DRG may be changed from low level to high level and then changed back to low level. Charges accumulated in the first node ND1 may be converted into a second reset voltage VR2 through the source follower transistor SFT and outputted during the second reset operation R2.

Subsequently, the second signal operation S2 may be performed at the fourth time t4. During a time period between the third time t3 and the fourth time t4, the second sub-transfer signal TS1_S2 may be changed from low level to high level and then changed back to low level. While the second sub-transfer signal TS1_S2 maintains high level, the second sub-transfer transistor TST1_S2 may be turned on for a time such as a dynamically determined or predetermined time and then turned off. The first node ND1 may be connected to the first photodiode PD1 while the second sub-transfer transistor TST1_S2 is turned on. Through this, charges stored in the second sub-region SBR2 of the first photodiode PD1 may be transferred to the first node ND1 (i.e., the first floating diffusion region FD1). The charges transferred to the first node ND1 may be converted into a second signal voltage VS2 by the source follower transistor SFT and outputted. The second signal voltage VS2 may mainly reflect charge data generated by the second sub-region SBR2 of the first photodiode PD1.

While the second sub-transfer transistor TST1_S2 is turned on, the first sub-transfer signal TS1_S1 may maintain low level or may be changed to high level as shown by a dotted line. In this step, when the first sub-transfer signal TS1_S1 maintains low level, the first sub-region SBR1 of the first photodiode PD1 may not be directly connected to the first node ND1. When the first sub-transfer signal TS1_S1 is changed to high level, not only the second sub-transfer transistor TST1_S2 but also the first sub-transfer transistor TST1_S1 is turned on.

As a result, both the first sub-region SBR1 and the second sub-region SBR2 of the first photodiode PD1 may be connected to the first node ND1.

Following the second operation OP2, the third operation OP3 may be performed. The third operation OP3 may include the third signal operation S3 and the third reset operation R3. That is, after the third signal operation S3 is first performed at a fifth time t5, the third reset operation R5 may be performed at a sixth time t6.

Specifically, during a time period between the fourth time t4 and the fifth time t5, the connection control signal DRG is changed from low level to high level to turn on the connection transistor DRT, and accordingly, the second node ND2 may be connected to the first node ND1. Further, after the connection control signal DRG is changed from low level to high level, the first sub-transfer signal TS1_S1 and the second sub-transfer signal TS1_S2 may be simultaneously changed from low level to high level and then changed back to low level. That is, in a state in which the connection transistor DRT is turned on, the first sub-transfer transistor TST1_S1 and the second sub-transfer transistor TST1_S2 may be simultaneously turned on and then turned off. While the first sub-transfer transistor TST1_S1 and the second sub-transfer transistor TST1_S2 are turned on, the first node ND1 may be connected to the first photodiode PD1 and the second node ND2. Accordingly, charges stored in the first sub-region SBR1 and the second sub-region SBR2 of the first photodiode PD1 and charges stored in the first node ND1 and the second node ND2 may be outputted together through the source follower transistor SFT as a third signal voltage VS3.

Subsequently, during a time period between the fifth time t5 and the sixth time t6, the reset signal RG may be changed from low level to high level and then changed back to low level. That is, the reset transistor RST may be turned on and then turned off. Since the connection transistor DRT maintains a turned-on state, the first node ND1 and the second node ND1 are in a connected state. When the reset transistor RST is turned on, the first node ND1 and the second node ND2 may be reset to a reset voltage (e.g., the third power voltage VDD3). At the sixth time t6, the voltage of the first node ND1 connected to the second node ND2 may be outputted as a third reset voltage VR3.

Following the third operation OP3, the fourth operation OP4 may be performed. The fourth operation OP4 may include the fourth reset operation R4 and the fourth signal operation S4. That is, after the fourth reset operation R4 is first performed at a seventh time t7, the fourth signal operation S4 may be performed at an eighth time t8.

Specifically, during a time period between the sixth time t6 and the seventh time t7, the switch control signal SW is changed from low level to high level to turn on the switch control transistor SWT. Since the connection transistor DRT also maintains a turned-on state, the first node ND1, the second node ND2, and the third node ND3 may be connected to each other. At the seventh time t7, the voltage of the first node ND1 connected to the second node ND2 and the third node ND3 may be outputted as a fourth reset voltage VR4.

Subsequently, during a time period between the seventh time t7 and the eighth time t8, the second transfer signal TS2 may be changed from low level to high level and then changed back to low level. That is, the second transfer transistor TST2 may be turned on and then turned off. While the second transfer transistor TST2 is turned on, the third node ND3 may be connected to the second photodiode PD2. Through this, charges stored in the second photodiode PD2 may be transferred to the third node ND3 (i.e., the second floating diffusion region FD2). The charges transferred to the third node ND3 may be converted into a fourth signal voltage VS4 by the source follower transistor SFT to be outputted through the second node ND2 and the first node ND1._The fourth signal voltage VS4 may mainly reflect charge data generated by the second photodiode PD2.

Following the fourth operation OP4, the fifth operation OP5 may be performed. The fifth operation OP5 may include the fifth signal operation S5 and the fifth reset operation R5. That is, after the fifth signal operation S5 is first performed at a ninth time t9, the fifth reset operation R5 may be performed at a tenth time t10.

Specifically, during a time period between the eighth time t8 and the ninth time t9, the second transfer signal TS2 may be changed from low level to high level again and then changed back to low level. That is, the second transfer transistor TST2 may be turned on and then turned off. While the second transfer transistor TST2 is turned on, the third node ND3 is connected to the second photodiode PD2 so that charges generated after the previous signal operation may be transferred to the third node ND3. Meanwhile, the third node ND3 is connected to the capacitor C1. The capacitor C1 may store overflowed charges generated by the second photodiode PD2. The charges stored in the third node ND3 may be converted into a fifth signal voltage VS5 by the source follower transistor SFT to be outputted through the second node ND2 and the first node ND1. The fifth signal voltage VS5 may mainly reflect data of charges accumulated in the capacitor C1.

Subsequently, the fifth reset operation R5 may be performed at the tenth time t10. During a time period between the ninth time t9 and the tenth time t10, the reset signal RG may be changed from low level to high level and then changed back to low level. That is, the reset transistor RST may be turned on and then turned off. A reset voltage (i.e., the second power voltage VDD2) may be applied to the second node ND2 while the reset transistor RST is turned on. In addition, the connection transistor DRT and the switch control transistor SWT are maintained in a turned-on state, and thus the third node ND3 and the first node ND1 are connected to the second node ND2, so that the reset voltage may also be applied to the third node ND3 and the first node ND1. Charges accumulated in the first node ND1 may be outputted as a fifth reset voltage VR5 through the source follower transistor SFT.

After the fifth operation OP5, the selection signal SEL and the switch control signal SW may be changed from high level to low level, and the reset signal RG may be changed from low level to high level.

As described above, in the readout of the pixel PX according to some example embodiments, the charges generated in the respective first sub-region SBR1 and second sub-region SBR2 of the first photodiode PD1 are separately sensed through the first operation OP1 and the second operation OP2. Accordingly, the charge data generated in the respective first sub-region SBR1 and second sub-region SBR2 may be acquired, and an auto-focusing function may be implemented using the data.

In addition, since even the charges accumulated in the second node ND2 is sensed through the third operation OP3, the first photodiode PD1 may have a larger full well capacity. In addition, since the charges accumulated in the second photodiode PD2 are sensed through the fourth operation OP4 and the charges accumulated in the capacitor C1 are sensed through the fifth operation OP5, the second photodiode PD2 may also have a larger full well capacity. Therefore, it may have a larger full well capacity.

In addition, since each operation may have a dynamic range from low illuminance to high illuminance, a larger maximum signal-to-noise ratio may be obtained with respect to a wide illuminance range, thereby improving the quality of the image sensor 10.

Hereinafter, an operation of a pixel circuit according to some example embodiments will be described. In the following embodiments, descriptions of the same components as those previously described will be omitted or simplified.

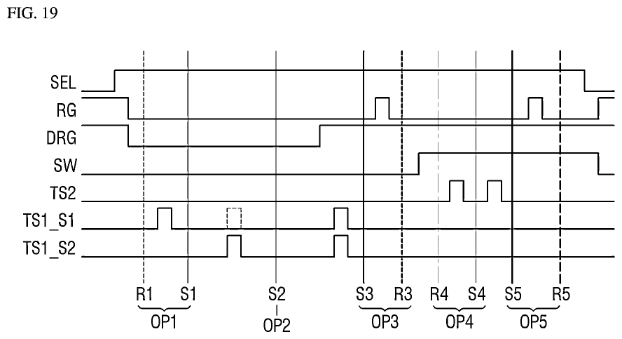

FIG. 19 is an example timing diagram for describing an operation of a pixel, which has the circuit structure of FIG. 17, according to some example embodiments.

Referring to FIG. 19, an operation according to these example embodiments is different from the operation of example embodiments of FIG. 18 in that the second operation OP2 performs the second signal operation S2 without performing the second reset operation R2.

More specifically, the operation is the same as that in example embodiments of FIG. 18 until performing the first signal operation S1. That is, after the first reset operation R1, the first signal operation S1 is performed to output the first signal voltage VS1 converted from the charges generated in the first sub-region SBR1.

Thereafter, the second signal operation S2 of the second operation OP2 may be performed without performing a separate reset operation. The second signal operation S2 is substantially the same as the second signal operation S2 according to example embodiments of FIG. 18. That is, the second sub-transfer signal TS1_S2 may be changed from low level to high level and then changed back to low level. While the second sub-transfer transistor TST1_S2 is turned on, the first sub-transfer signal TS1_S1 may maintain low level or may be changed to high level as shown by a dotted line. While the second sub-transfer transistor TST1_S2 is turned on, the second sub-region SBR2 and the first node ND1 may be connected to each other. The charges of the first sub-region SBR1 transferred in the previous first signal operation S1 and the charges of the second sub-region SBR2 transferred in the second signal operation S2 are stored together in the first node ND1. The charges stored in the first node ND1 may be converted into the second signal voltage VS2 by the source follower transistor SFT and outputted. The second signal voltage VS2 may reflect charge data generated in both the first sub-region SBR1 and the second sub-region SBR2. Data related to the charges generated in the second sub-region SBR2 may be calculated using a difference between the second signal voltage VS2 and the first signal voltage VS1.

Since the third operation OP3 to the fifth operation OP5 after the second operation OP2 are substantially the same as those in example embodiments of FIG. 18, a redundant description thereof will be omitted.

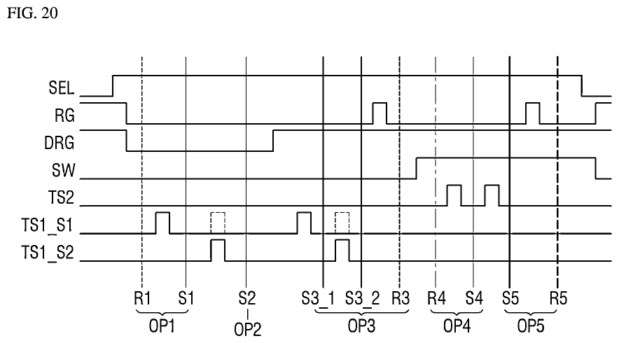

FIG. 20 is an example timing diagram for describing an operation of a pixel, which has the circuit structure of FIG. 17, according to still some example embodiments.

Referring to FIG. 20, an operation according to these example embodiments is different from that of example embodiments of FIG. 19 in that a third signal operation of the third operation OP3 includes a third-first signal operation S3_1 and a third-second signal operation S3_2.

That is, after the second operation OP2 is performed, the third operation OP3 may be performed. The third operation OP3 includes the third-first signal operation S3_1, in which the first sub-transfer transistor TST1_S1 is turned on and turned off, and then a third-first signal voltage VS3_1 is outputted, the third-second signal operation S3_2, in which the second sub-transfer transistor TST1_S2 and/or the first sub-transfer transistor TST1_S1 is turned on and turned off, and then a third-second signal voltage VS3_2 is outputted, and the third reset operation R3 in which the reset transistor RST is turned on and turned off, and then the third reset voltage VR3 is outputted, under the turned-on state of the connection transistor DRT.

In the third-first signal operation S3_1, in a state in which the first node ND1 is connected to the second node ND2, it may also be connected to the first sub-region SBR1. In the third-second signal operation S3_2, in a state in which the first node ND1 is connected to the second node ND2, it may also be connected to the second sub-region SBR2 and/or the first sub-region SBR1.

In these example embodiments, not only charge data of the first sub-region SBR1 and charge data of the second sub-region SBR2 transferred to the first node ND1 may be obtained independently through the first operation OP1 and the second operation OP2, but also charge data transferred from the first sub-region SBR1 and charge data transferred from the second sub-region SBR2 may be measured separately in a state, in which the first node ND1 is connected to the second node ND2, through the third-first signal operation S3_1 and the third-second signal operation S3_2. Accordingly, since the third operation OP3 may have a more extended dynamic range with respect to each of the first sub-region SBR1 and the second sub-region SBR2, auto-focusing precision may be further improved.

The operation methods of example embodiments are not limited to those exemplified above, and more various operation methods of separately sensing the first sub-region SBR1 and the second sub-region SBR2 for each operation may be applied.

Hereinafter, more various example embodiments of an image sensor will be described.

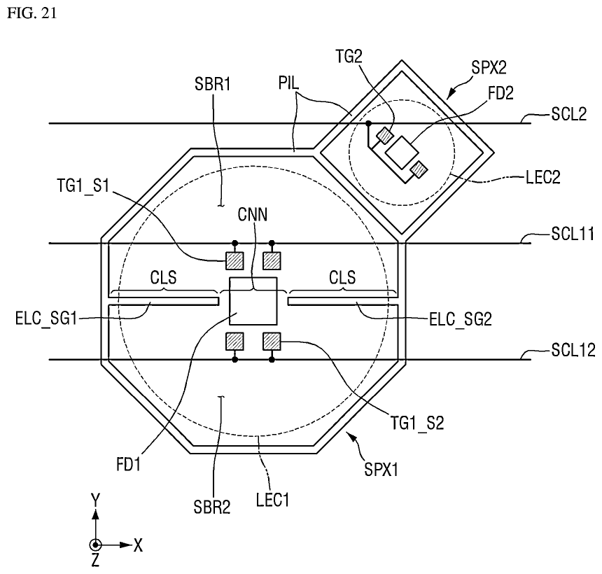

FIG. 21 is a layout view of one pixel according to some example embodiments.

FIG. 21 illustrates that a method of dividing the first sub-region SBR1 and the second sub-region SBR2 may be various. Referring to FIG. 21, one pixel of an image sensor according to these example embodiments is different from example embodiments of FIG. 6 in that the first segment ELC_SG1 and the second segment ELC_SG2 of the potential level controller ELC may extend respectively from centers of facing edges to the first direction X, the first sub-region SBR1 is located on one side of the potential level controller ELC in the second direction Y, and the second sub-region SBR2 is located on the other side of the potential level controller ELC in the second direction Y. That is, in FIG. 21, the potential level controller ELC may divide the first photoelectric conversion region LEC, for example, in the vertical direction in plan view.

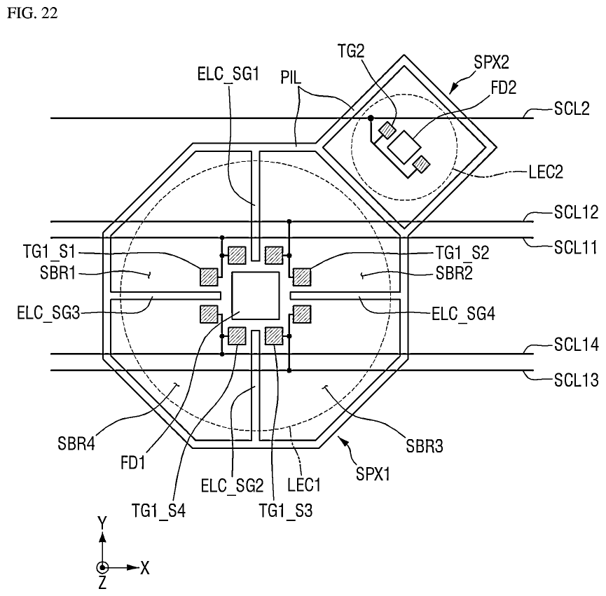

Example embodiments of FIG. 6 may be useful for implementing auto-focusing by measuring a distance in the first direction X (e.g., the horizontal direction), and example embodiments of FIG. 22 may be useful for implementing auto-focusing by measuring a distance in the second direction Y (e.g., the vertical direction).

Although not shown in the drawing, the first segment ELC_SG1 and the second segment ELC_SG2 may extend in a diagonal direction inclined with respect to the first direction X and the second direction Y.

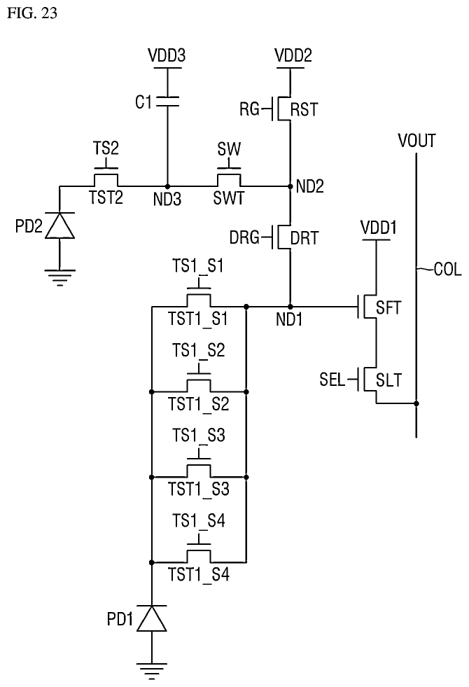

FIG. 22 is a layout view of one pixel according to still some example embodiments. FIG. 23 is a circuit diagram of the one pixel of FIG. 22.

FIGS. 22 and 23 illustrate that the first photoelectric conversion region LEC1 may be divided into three or more sub-regions. Referring to FIGS. 22 and 23, the potential level controller ELC may include the first segment ELC_SG1 and the second segment ELC_SG2, which extend respectively from centers of facing edges in the second direction Y, and a third segment ELC_SG3 and a fourth segment ELC_SG4 which extend respectively from centers of other facing edges in the first direction X. The first segment ELC_SG1 and the second segment ELC_SG2 may be opposite to each other while being spaced apart from each other in the second direction Y, and the third segment ELC_SG3 and the fourth segment ELC_SG4 may be opposite to each other while being spaced apart from each other in the first direction X. Four regions surrounded by the segments may be four sub-regions SBR1, SBR2, SBR3, and SBR4, respectively.

A sub-transfer transistor may be disposed in each of the sub-regions SBR1, SBR2, SBR3, and SBR4. For example, the first sub-transfer transistor TST1_S1, the second sub-transfer transistor TST1_S2, a third sub-transfer transistor TST1_S3, and a fourth sub-transfer transistor TST1_S4 may be disposed in the first sub-region SBR1, the second sub-region SBR2, the third sub-region SBR3, and the fourth sub-region SBR4, respectively. The first sub-transfer gate TG1_S1 of the first sub-transfer transistor TST1_S1 may be connected to the first sub-transfer line SCL11 to receive the first sub-transfer signal TS1_S1. The second sub-transfer gate TG1_S2 of the second sub-transfer transistor TST1_S2 may be connected to the second sub-transfer line SCL12 to receive the second sub-transfer signal TS1_S2. A third sub-transfer gate TG1_S3 of the third sub-transfer transistor TST1_S3 may be connected to a third sub-transfer line SCL13 to receive a third sub-transfer signal TS1_S3. A fourth sub-transfer gate TG1_S4 of the fourth sub-transfer transistor TST1_S4 may be connected to a fourth sub-transfer line SCL14 to receive a fourth sub-transfer signal TS1_S4.

The sub-regions SBR1, SBR2, SBR3, and SBR4 may share the first floating diffusion region FD1. The first to fourth sub-transfer transistors TST1_S1, TST1_S2, TST1_S3, and TST1_S4 may be connected in parallel between the first photodiode PD1 and the first node ND1.

In these example embodiments, since one first photoelectric conversion region LEC1 is divided into four sub-regions SBR1, SBR2, SBR3, and SBR4, charge data generated in each sub-region may be independently measured. Accordingly, more precise auto-focusing may be implemented.

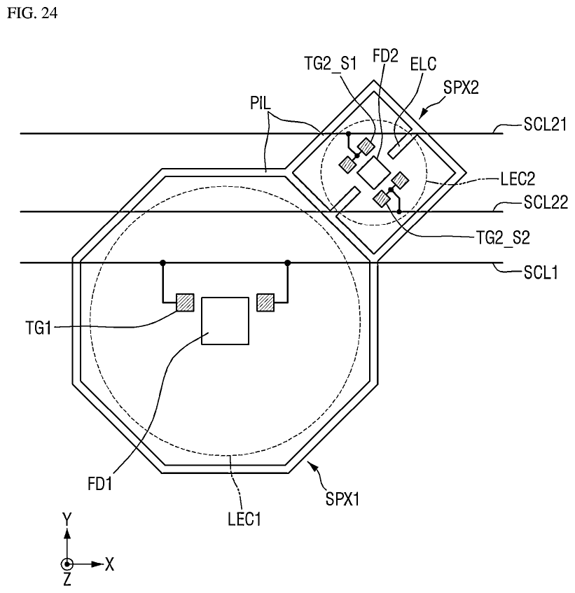

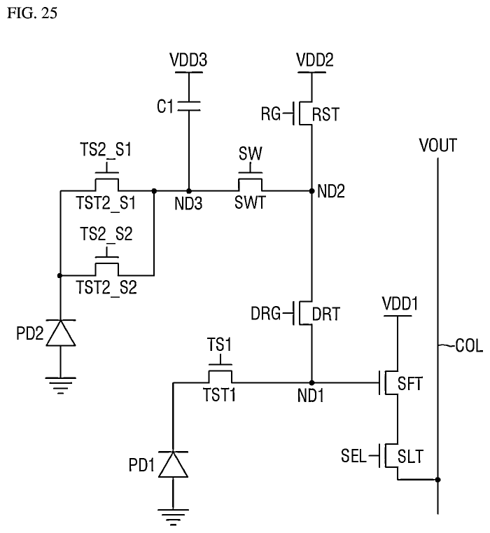

FIG. 24 is a layout view of one pixel according to still some example embodiments. FIG. 25 is a circuit diagram of one pixel of FIG. 24.

Example embodiments of FIGS. 24 and 25 illustrates that the second photoelectric conversion region LEC2 of the second sub-pixel SPX2, which has a smaller area than the first photoelectric conversion region LEC1, may be divided into a plurality of sub-regions SBR1 and SBR2.

As illustrated in FIGS. 24 and 25, the second sub-pixel SPX2 includes the potential level controller ELC that divides the second photoelectric conversion region LEC2 into the first sub-region SBR1 and the second sub-region SBR2. The first transfer gate TG1 is disposed on the first photoelectric conversion region LEC1, and the second transfer gate TG2 is disposed on the second photoelectric conversion region LEC2. In these example embodiments, the second transfer gate TG2 includes a first sub-transfer gate TG2_S1 overlapping the first sub-region SBR1 of the second photoelectric conversion region LEC2 and a second sub-transfer gate TG2_S2 overlapping the second sub-region SBR2 of the second photoelectric conversion region LEC2.

The first sub-transfer gate TG2_S1 may be configured to mainly transfer charges generated in the first sub-region SBR1 to the second floating diffusion region FD2. The second sub-transfer gate TG2_S2 is configured to mainly transfer charges generated in the second sub-region SBR2 to the second floating diffusion region FD2. A first sub-transfer transistor TST2_S1 including the first sub-transfer gate TG2_S1 and a second sub-transfer transistor TST2_S2 including the second sub-transfer gate TG2_S2 may be connected to the second floating diffusion region FD2 at their one ends. For example, the first sub-transfer transistor TST2_S1 and the second sub-transfer transistor TST2_S2 may share one floating diffusion region. The first sub-transfer transistor TST2_S1 and the second sub-transfer transistor TST2_S2 of the second transfer gate TG2 may be connected in parallel between the second photodiode PD2 and the second floating diffusion region FD2 (i.e., the third node ND3).

Since a method of independently measuring light amounts of the first sub-region SBR1 and the second sub-region SBR2 of the second photoelectric conversion region LEC2 using the first sub-transfer transistor TST2_S1 and the second sub-transfer transistor TST2_S2 is substantially the same as that applied with respect to the sub-regions of the first photoelectric conversion region in example embodiments of FIGS. 18 to 20, a description thereof will be omitted.

This embodiment is configured such that the second photoelectric conversion region LEC2 of the second sub-pixel SPX2 is divided into the first sub-region SBR1 and the second sub-region SBR2, and the sub-regions SBR1 and SBR2 are driven independently. Accordingly, an auto-focusing function may be implemented through the amounts of light incident on the sub-regions SBR1 and SBR2 of the second sub-pixel SPX2.

Although not illustrated in the drawing, both the first photoelectric conversion region LEC1 and the second photoelectric conversion region LEC2 may have a plurality of sub-regions. As the number of sub-regions increases, a more precise auto-focusing function may be implemented.

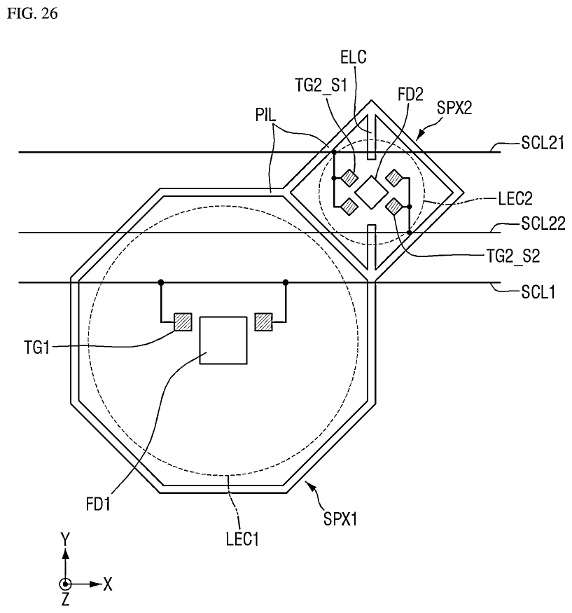

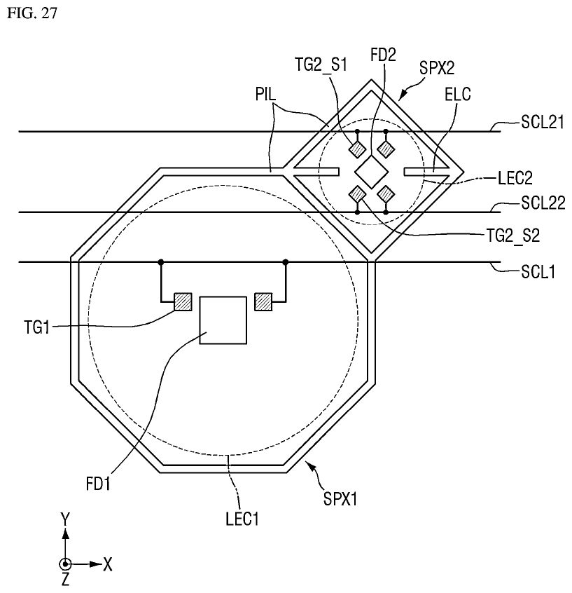

Example embodiments of FIG. 24 illustrates that the potential level controller ELC (or the segments thereof), which divides the second sub-pixel SPX2 into the first sub-region SBR1 and the second sub-region SBR2, extends in a diagonal direction intersecting the first direction X and the second direction Y, but example embodiments are not limited thereto. More various embodiments are illustrated in FIGS. 26 and 27.

FIGS. 26 and 27 are layout views of one pixel according to some example embodiments.

The potential level controller ELC, which divides the second sub-pixel SPX2 into the first sub-region SBR1 and the second sub-region SBR2, may extend in the first direction X as shown in FIG. 26 or may extend in the second direction Y as shown in FIG. 27.

Although not shown in the drawing, the potential level controller ELC, which divides the second sub-pixel SPX2 into the first sub-region SBR1 and the second sub-region SBR2, may include both a portion extending in the first direction X and a portion extending in the second direction Y similarly to example embodiments of FIG. 22. In addition, even in the case of the potential level controller ELC dividing the first sub-pixel SPX2, it may extend in the diagonal direction intersecting the first direction X and the second direction Y as shown in FIG. 24. Further, various combinations of example embodiments are possible.

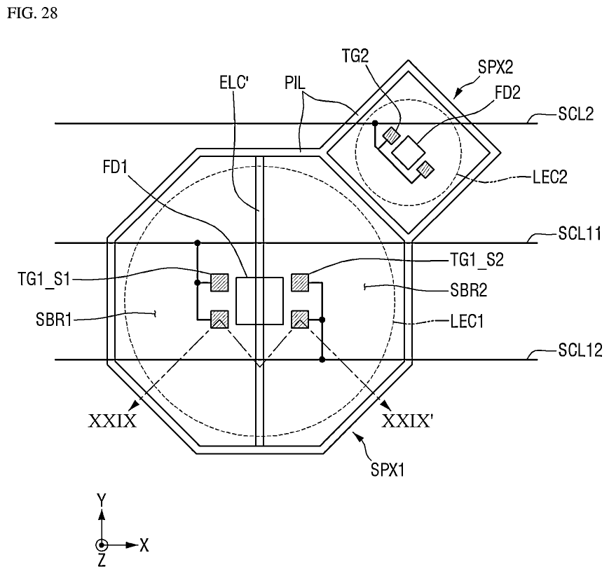

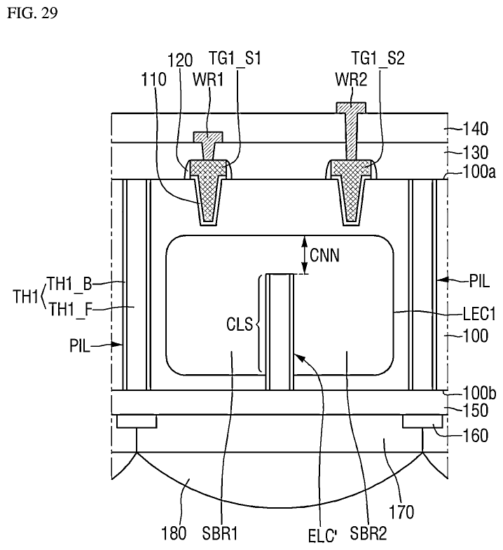

FIG. 28 is a layout view of one pixel according to still some example embodiments. FIG. 29 is a cross-sectional view taken along line XXIX-XXIX′ of FIG. 28.

In FIGS. 28 and 29, a potential level controller ELC′ of a different type from that of example embodiments of FIG. 6 is applied.

Specifically, the potential level controller ELC′ is not divided into segments, but crosses facing edges of the first sub-pixel SPX1 in the second direction Y to completely divide the first sub-region SBR1 and the second sub-region SBR2 in plan view. The potential level controller ELC′ may also overlap the first floating diffusion region FD1 located at the center of the first sub-pixel SPX1.

As in example embodiments of FIG. 6, when a through isolation insulating layer that completely penetrates a substrate is applied as the potential level controller ELC′, it may not function as a partial isolation layer because the arrangement as in FIG. 28 completely blocks the movement of charges between the first sub-region SBR1 and the second sub-region SBR2. However, in this example embodiment, as shown in FIG. 29, a trench isolation layer TRI that does not completely penetrate the substrate 100 is applied as the potential level controller ELC′, so that the physical connection section CNN is secured between the first sub-region SBR1 and the second sub-region SBR2.

The potential level controller ELC′, which is the trench isolation layer TRI, extends from the second surface 100b of the substrate 100 toward the first surface 100a thereof, but terminates before reaching the first surface 100a of the substrate 100. For example, one end of the trench isolation layer TRI is placed on the second surface 100b of the substrate 100, but the other end thereof is placed inside the substrate 100. The other end of the trench isolation layer TRI may be disposed inside the first photoelectric conversion region LEC1. As a result, the first photoelectric conversion region LEC1 may include the isolation section CLS in which the first sub-region SBR1 and the second sub-region SBR2 are physically isolated by the trench isolation layer TRI in the third direction and the connection section CNN beyond the other end of the trench isolation layer TRI. Accordingly, the potential level of the potential level controller ELC′ formed by the trench isolation layer TRI may be located between the maximum potential of the sub-regions SBR1 and SBR2 and the shut-off voltage of the sub-transfer transistors TST1_S1 and TST1_S2, similarly to that shown in FIG. 9. Accordingly, the operation may be similar to that of example embodiments of FIG. 6 in which the potential level of the potential level controller ELC is adjusted through the spaced segments.

Although not shown in the drawing, the arrangement of the potential level controller ELC′ illustrated in FIG. 28 may be variously modified. For example, the potential level controller ELC′ may extend in the first direction X. Alternatively, all the potential level controllers ELC′ respectively extending in the first direction X and the second direction Y may be provided to partition four sub-regions. In addition, it may extend in a diagonal direction intersecting the first direction X and the second direction Y. Further, the potential level controller ELC′ may be applied to the second sub-pixel SPX2.

Furthermore, the potential level controller ELC′ illustrated in FIG. 28 may be combined with the potential level controller ELC illustrated in FIG. 6. For example, in the first photoelectric conversion region LEC1, as the potential level controller extending in the second direction Y, a potential level controller of the same type as in example embodiments of FIG. 6 may be applied, and as the potential level controller extending in the first direction X, a potential level controller of the same type as in example embodiments of FIG. 28 may be applied. In addition, the potential level controller of the same type as in example embodiments of FIG. 6 may be applied to the first sub-pixel SPX1, and the potential level controller of the same type as in example embodiments of FIG. 28 may be applied to the second sub-pixel SPX2, and vice versa.

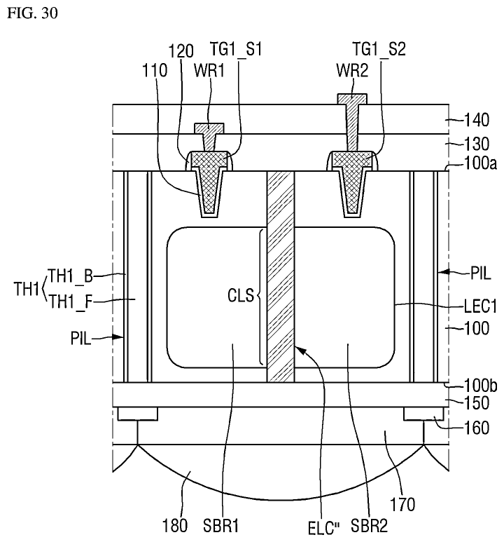

FIG. 30 is a cross-sectional view of one pixel according to still some example embodiments. Example embodiments of FIG. 30 illustrates another type that can be applied as the potential level controller ELC″.

Referring to FIG. 30, a potential level controller ELC″ according to these example embodiments is different from the potential level controller ELC of example embodiments of FIG. 6 in that it includes, instead of the isolation insulating layer, an impurity doped region having a conductivity type opposite to that of the first photoelectric conversion region LEC1. When the first photoelectric conversion region LEC1 has an n-type conductivity type, the potential level controller ELC″ includes a high concentration of p-type conductivity type impurities. The size of a potential barrier that blocks the movement of charges may vary according to the concentration of the p-type conductivity type impurities. As such, even by adjusting the impurity concentration, the potential level between the first sub-region SBR1 and the second sub-region SBR2 may be controlled. That is, when the impurity concentration of the potential level controller ELC″ is adjusted to be located between the maximum potential of the sub-regions and the shut-off voltage of the sub-transfer transistors similarly to FIG. 9, it is possible to partially block charge transfer between the first sub-region SBR1 and the second sub-region SBR1.

Although the drawing illustrates that the potential level controller ELC, which includes the opposite conductivity type impurity region, has the same shape as that in example embodiments of FIGS. 6 to 8, it may have the same arrangement and shape as that of FIGS. 28 and 29.

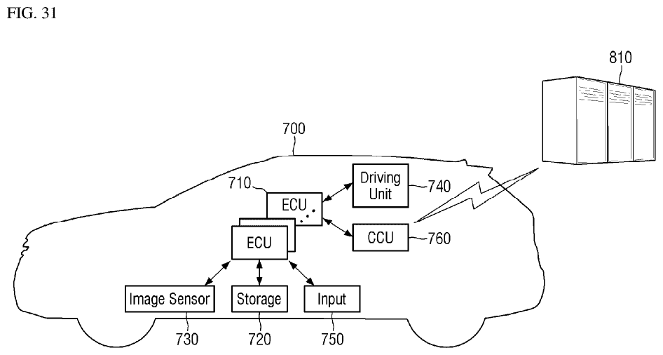

Hereinafter, a vehicle including an image sensor according to some example embodiments will be described with reference to FIG. 31.

FIG. 31 is a diagram of a vehicle including an image sensor according to some example embodiments.

Referring to FIG. 31, a vehicle 700 may include a plurality of electronic control units (ECU) 710, and a storage 720.

Each of the plurality of electronic control units 710 may be electrically, mechanically, and communicatively connected to at least one of a plurality of devices provided in the vehicle 700, and may control an operation of at least one device based on any one function performing command.

Here, the plurality of devices may include an image sensor 730 that acquires an image required to perform at least one function, and a driving unit 740 that performs at least one function.

The image sensors according to various embodiments described above may be applied as the image sensor 730. The image sensor 730 may correspond to an automotive image sensor.

The driving unit 740 may include a fan and a compressor of an air conditioning device, a fan of a ventilation device, an engine and a motor of a power device, a motor of a steering device, a motor and a valve of a braking device, an opening/closing device of a door or a tailgate, and the like.

The plurality of electronic control units 710 may communicate with the image sensor 730 and the driving unit 740 using, for example, at least one of Ethernet, low voltage differential signal (LVDS) communication, or local interconnect network (LIN) communication.

The plurality of electronic control units 710 may determine whether a function needs to be performed based on the information acquired through the image sensor 730, control an operation of the driving unit 740 performing the function when it is determined that the corresponding function needs to be performed, and meanwhile control the amount of the operation based on the acquired information. In this case, the plurality of electronic control units 710 may store the acquired image in the storage 720 or read and use the information stored in the storage 720.

The plurality of electronic control units 710 may also control the operation of the driving unit 740 performing the corresponding function based on the function performing command inputted through an input unit 750, and may also check the set amount corresponding to information inputted through the input unit 750 and control the operation of the driving unit 740 performing the corresponding function based on the checked set amount.

Each electronic control unit 710 may independently control any one function, or may control any one function in association with other electronic control devices.

For example, when the distance to an obstacle detected through a distance detector is within a reference distance, the electronic control device of a collision avoidance device may output a warning sound regarding the collision with the obstacle through a speaker.

The electronic control device of an autonomous driving control device may perform autonomous driving, in association with the electronic control device of the vehicle terminal, the electronic control device of the image acquisition unit, and the electronic control device of the collision avoidance device, by receiving navigation information, road image information, and distance information from obstacles and controlling the power device, the braking device, and the steering device using the received information.

A connectivity control unit (CCU) 760 is electrically, mechanically, and communicatively connected to each of the plurality of electronic control units 710, and performs communication with each of the plurality of electronic control units 710.

That is, the connectivity control unit 760 may directly perform communication with the plurality of electronic control units 710 provided inside the vehicle, may perform communication with an external server, and may perform communication with an external terminal through an interface.

Here, the connectivity control unit 760 may perform communication with the plurality of electronic control units 710, and may perform communication with a server 810 using an antenna (not illustrated) and RF communication.

In addition, the connectivity control unit 760 may perform communication with the server 810 through wireless communication. In this case, the wireless communication between the connectivity control unit 760 and the server 810 is possible through various wireless communication methods, in addition to a Wi-Fi module and a wireless broadband (WiBro) module, such as global system for mobile communication (GSM), code division multiple access (CDMA), wideband code division multiple access (WCDMA), universal mobile telecommunications system (UMTS), time division multiple access (TDMA), and long term evolution (LTE).

The image sensor described above is a sort of an optical sensor, and the spirit according to example embodiments is applicable to other types of sensors such as a fingerprint sensor, a distance measurement sensor, and the like that detect the amount of incident light using a semiconductor, in addition to the image sensor.

Any or all of the elements described with reference to any of the figures may communicate with any or all other elements described with reference to the respective figures; for example, any element may engage in one-way and/or two-way and/or broadcast communication with any or all other elements in the figures, to transfer and/or exchange information such as but not limited to data and/or commands, in a serial and/or parallel manner, via a wireless and/or a wired bus (not illustrated). Information transferred and/or exchanged may be encoded in an analog and/or a digital manner; example embodiments are not limited thereto.

In concluding the detailed description, those skilled in the art will appreciate that many variations and modifications may be made to variously described example embodiments without substantially departing from the principles of the present invention. Therefore, the disclosed example embodiments are used in a generic and descriptive sense only and not for purposes of limitation. Furthermore example embodiments are not necessarily mutually exclusive with one another. For example, some example embodiments may include one or more features described with reference to one or more figures, and may also include one or more other features described with reference to one or more other figures.

1. An image sensor comprising:
a first sub-pixel comprising a first photoelectric conversion region, a first floating diffusion region, and a first transfer transistor that is configured to transfer charges accumulated in the first photoelectric conversion region to the first floating diffusion region; and
a second sub-pixel disposed adjacent to the first sub-pixel, and comprising a second photoelectric conversion region, a second floating diffusion region, and a second transfer transistor that is configured to transfer charges accumulated in the second photoelectric conversion region to the second floating diffusion region,
wherein the first sub-pixel has a larger area than the second sub-pixel,
the first photoelectric conversion region comprises a first sub-region and a second sub-region that is partitioned by a potential level isolation region that is configured to at least partially block movement of charges, and
the first transfer transistor comprises a first sub-transfer transistor configured to transfer charges accumulated in the first sub-region to the first floating diffusion region, and a second sub-transfer transistor configured to transfer charges accumulated in the second sub-region to the first floating diffusion region.

2. The image sensor of claim 1, wherein the first sub-pixel and the second sub-pixel are each surrounded by a pixel isolation layer that comprises a through isolation insulating layer.

3. The image sensor of claim 2, wherein the through isolation insulating layer is configured to at least partially block movement of charges.

4. The image sensor of claim 1, wherein the potential level isolation region comprises a first segment extending from a first edge of the first sub-pixel and a second segment extending from a second edge of the first sub-pixel, and an end of the first segment and an end of the second segment are spaced apart from each other.

5. The image sensor of claim 4, wherein the second segment is collinear with the first segment.

6. The image sensor of claim 5, wherein the first sub-region and the second sub-region have the same area.

7. The image sensor of claim 4, wherein the first segment and the second segment comprise a first through isolation insulating layer configured to at least partially block movement of charges.

8. The image sensor of claim 7, wherein each of the first sub-pixel and the second sub-pixel is surrounded by a pixel isolation layer comprising a second through isolation insulating layer configured to block movement of charges.

9. The image sensor of claim 8, wherein the first through isolation insulating layer and the second through isolation insulating layer comprise a same material, and the first segment and the second segment are branched from the pixel isolation layer.

10. The image sensor of claim 4, wherein the first floating diffusion region is between the end of the first segment and the end of the second segment.

11. The image sensor of claim 1, wherein the potential level isolation region comprises a trench isolation layer configured to at least partially block movement of charges.

12. The image sensor of claim 11, wherein the potential level isolation region extends from a first edge of the first sub-pixel to a second edge of the first sub-pixel.

13. The image sensor of claim 1, wherein the first photoelectric conversion region has a larger area than the second photoelectric conversion region in plan view.

14. The image sensor of claim 1, wherein the potential level isolation region is configured to have a potential level of the potential level isolation region between a maximum potential of the first sub-region and the second sub-region and a shut-off voltage of the first sub-transfer transistor and the second sub-transfer transistor.

15.-18. (canceled)

19. An image sensor comprising:
a substrate comprising a first surface and a second surface opposite to each other;
a pixel isolation layer configured to penetrate the substrate from the first surface to the second surface and to partition a first sub-pixel region and a second sub-pixel region;
a first photoelectric conversion region and a first floating diffusion region that are in the substrate and in the first sub-pixel region;
a second photoelectric conversion region and a second floating diffusion region that are in the substrate and in the second sub-pixel region;
a potential level isolation region configured to at least partially block movement of charges, the potential level isolation region in the substrate and partitioning the first photoelectric conversion region into a first sub-region and a second sub-region; and
a transfer gate on the substrate, the transfer gate comprising a first sub-transfer gate on the first sub-region and configured to control electrical connection between the first sub-region and the first floating diffusion region, a second sub-transfer gate on the second sub-region and configured to control electrical connection between the second sub-region and the first floating diffusion region, and a second transfer gate on the second sub-pixel region and configured to control electrical connection between the second photoelectric conversion region and the second floating diffusion region.

20. The image sensor of claim 19, wherein the potential level isolation region comprises a first segment extending from a first edge of the first sub-pixel region and a second segment extending from a second edge of the first sub-pixel region in plan view, and an end of the first segment and an end of the second segment are spaced apart from each other.

21. The image sensor of claim 20, wherein each of the first segment and the second segment penetrates the substrate from the first surface to the second surface.

22. The image sensor of claim 21, wherein the first segment and the second segment each comprise a same material as the pixel isolation layer and branched from the pixel isolation layer.

23. The image sensor of claim 19, wherein the potential level isolation region extends from a first edge of the first sub-pixel region to a second edge of the first sub-pixel region.

24. The image sensor of claim 23, wherein the potential level isolation region comprises a trench isolation layer extending from the second surface of the substrate and having an end located within the first photoelectric conversion region.
